(19) United States
(12) Patent Application Publication
(10) Pub. No.: US 2026/0098722 A1
(43) Pub. Date: Apr. 9, 2026

(54) THREE-DIMENSIONAL SCANNER

(71) Applicant: Keyence Corporation, Osaka (JP)

(72) Inventors: Shingo MATSUMURA, Osaka (JP); Masaki FUJIWARA, Osaka (JP)

(73) Assignee: Keyence Corporation, Osaka (JP)

(21) Appl. No.: 19/314,095

(22) Filed: Aug. 29, 2025

(30) Foreign Application Priority Data
Oct. 7, 2024 (JP) 2024-175784

(51) Int. Cl. G01B 11/25; G06F 30/12

(52) U.S. Cl. CPC G01B 11/2504; G01B 11/2513; G06F 30/12

(57) ABSTRACT

Alignment between a plurality of pieces of three-dimensional data acquired by scanning a workpiece can be performed with high accuracy while reducing a burden on a user. A three-dimensional scanner includes a posture calculation unit that calculates an arrangement posture different from a first arrangement posture based on first three-dimensional data acquired by a data acquisition unit, an overlap region estimation unit that estimates an overlap region between three-dimensional data acquired by the data acquisition unit in a state of being arranged in the arrangement posture calculated by the posture calculation unit and the first three-dimensional data acquired by the data acquisition unit, and a display control unit that displays an evaluation index based on the amount of overlap region estimated by the overlap region estimation unit on a display unit.

### CROSS-REFERENCE TO RELATED APPLICATIONS

The present application claims foreign priority based on Japanese Patent Application No. 2024-175730, filed Oct. 7, 2024, the contents of which are incorporated herein by reference.

### BACKGROUND OF THE INVENTION

### 1. Technical Field

The disclosure relates to a three-dimensional scanner, a three-dimensional measurement method, and a storage medium storing a three-dimensional measurement program.

### 2. Description of the Related Art

For example, JP2024-24328A discloses a three-dimensional scanner that scans a workpiece to generate three-dimensional data.

This type of three-dimensional scanner is configured to be able to measure the three-dimensional shape of the workpiece by irradiating the workpiece with mainly structured illumination light and capturing and analyzing distortion of the illumination light by a camera.

Since a shape of the workpiece obtained by one scan by the three-dimensional scanner is limited to a range captured by the camera, in order to acquire a shape of a portion not captured by the camera, it is necessary to scan the workpiece or the three-dimensional scanner multiple times while changing a relative positional relationship between the workpiece and the three-dimensional scanner and to align and combine pieces of scan data.

However, for example, in order to scan the entire workpiece such as a front surface and a back surface of the workpiece, it is necessary to repeat multiple times of scanning while changing a position and an orientation of the workpiece. However, it is up to the user to determine which position and orientation to mount the workpiece, and a plurality of pieces of scan data may not be correctly combined.

That is, as a method for aligning the plurality of pieces of scan data, there are a method for mechanically aligning the plurality of pieces of scan data by using a high-accuracy stage or robot arm, a method for aligning the plurality of pieces of scan data by pattern matching by using luminance or shape features of pieces of scanned data, and a hybrid method for mechanically aligning approximate positions and precisely aligning the plurality of pieces of scan data by matching. In addition, there is also a method for capturing the position of the three-dimensional scanner with another camera or the like without moving an object to align the position.

Mechanical methods are difficult to achieve alignment with high accuracy. In addition, for example, when the entire periphery of the workpiece is to be scanned, a surface in contact with a stage surface cannot be scanned in a normal stage, and it is necessary to remount the workpiece.

The matching method has an advantage that alignment accuracy corresponding to accuracy of the scan data can be realized regardless of a size of the object, but it is necessary to provide an overlap region between a plurality of pieces of data to be aligned, and the position is not determined unless there is some mark or feature point in the luminance and shape of the region. Thus, at the time of scanning, it is necessary to consider which region is acquired by which scan, whether or not a characteristic mark can be arranged in the overlap region between the plurality of pieces of scan data, and whether or not the workpiece and the camera can be physically arranged in a relative positional relationship to be scanned, and there is a problem that not only a degree of difficulty of alignment is high but also advanced know-how is required for accurate measurement.

In addition, as to whether or not the characteristic mark can be arranged in the overlap region between the plurality of pieces of scan data, it is necessary to actually scan how many features are to be arranged, collate a measured value with data and design values of other measuring instruments, and verify the result, and trial and error has been required.

### SUMMARY OF THE INVENTION

The disclosure has been made in view of such a point, and an object thereof is to enable alignment between a plurality of pieces of three-dimensional data acquired by scanning a workpiece with high accuracy while reducing a burden on a user.

In order to achieve the above object, according to one embodiment of the disclosure, a three-dimensional scanner that generates combined three-dimensional data of a workpiece by generating three-dimensional data of the workpiece arranged in different arrangement postures and combining the pieces of three-dimensional data can be premised. The three-dimensional scanner includes a data acquisition unit that acquires first three-dimensional data of a workpiece arranged in a first arrangement posture, a posture calculation unit that calculates an arrangement posture different from the first arrangement posture based on the first three-dimensional data acquired by the data acquisition unit, an overlap region estimation unit that estimates an overlap region between the three-dimensional data to be acquired by the data acquisition unit in a state of being arranged in the arrangement posture calculated by the posture calculation unit and the first three-dimensional data acquired by the data acquisition unit, and a display control unit that displays an evaluation index based on the amount of overlap region estimated by the overlap region estimation unit on a display unit.

According to this configuration, the overlap region between the first three-dimensional data of the workpiece arranged in the first arrangement posture and the three-dimensional data of the workpiece arranged in the arrangement posture different from the first arrangement posture is estimated by the overlap region estimation unit. Since the evaluation index based on the amount of overlap region is displayed on the display unit, the user can specify the arrangement posture of the workpiece in which the alignment can be performed with high accuracy with reference to the evaluation index without trial and error.

According to another embodiment of the disclosure, a three-dimensional measurement method for generating combined three-dimensional data of a workpiece by generating pieces of three-dimensional data of the workpiece arranged in different arrangement postures and combining the pieces of three-dimensional data can be premised. The three-dimensional measurement method can include acquiring first three-dimensional data of the workpiece arranged in a first arrangement posture, calculating an arrangement posture different from the first arrangement posture based on the acquired first three-dimensional data, estimating an overlap region between the three-dimensional data acquired by a data acquisition unit in a state of being arranged in the calculated arrangement posture and the first three-dimensional data acquired by the data acquisition unit, and displaying an evaluation index based on the estimated amount of overlap region on a display unit.

According to still another embodiment of the disclosure may be a storage medium storing a three-dimensional measurement program for causing a computer to execute a three-dimensional measurement method for generating combined three-dimensional data of a workpiece by generating pieces of three-dimensional data of the workpiece arranged in different arrangement postures and combining the pieces of three-dimensional data.

As described above, since the overlap region between the first three-dimensional data of the workpiece arranged in the first arrangement posture and the three-dimensional data acquired in the state of being arranged in the different arrangement postures can be estimated and the evaluation index based on the estimated amount of overlap region can be provided to the user, alignment between a plurality of pieces of three-dimensional data acquired by scanning the workpiece can be performed with high accuracy while reducing a burden on a user.

### BRIEF DESCRIPTION OF THE DRAWINGS

FIG. 1 is a diagram illustrating an overall configuration of a three-dimensional scanner according to an embodiment of the invention;

FIG. 2 is a block diagram of the three-dimensional scanner;

FIG. 3 is a side view of a measurement unit and a pedestal;

FIG. 4 is a block diagram of the measurement unit;

FIG. 5 is a diagram illustrating a configuration example of a module;

FIG. 6 is a flowchart illustrating an example of scan processing in a case where there is no CAD data of a workpiece;

FIG. 7 is a diagram illustrating an example of a user interface screen displayed at the start of measurement;

FIG. 8 is a diagram illustrating an example of a user interface screen displayed when posture candidates are presented;

FIG. 9 is a diagram illustrating an example of a user interface screen displayed when selection of a posture candidate is accepted;

FIG. 10 is a diagram illustrating an example of a user interface screen in which a model of a determined arrangement posture is superimposed and displayed on a live image;

FIG. 11 is a flowchart illustrating an example of alignment processing;

FIG. 12 is a schematic view related to hidden surface removal;

FIG. 13 is a flowchart illustrating an example of processing of extracting a shape feature and an image feature;

FIG. 14 is a flowchart illustrating an example of extraction processing in a case where a relationship among a virtual object, a virtual ground, and a virtual tilting table is adjusted;

FIG. 32 is a color map based on a difference in dimension between scan data of the workpiece and the CAD data;

FIG. 33A is a diagram illustrating an example in which cross-section measurement is performed on the scan data of the workpiece; and

FIG. 33B is a diagram illustrating an example in which the cross-section measurement is performed on the CAD data of the workpiece.

### DETAILED DESCRIPTION

Hereinafter, an embodiment of the invention will be described in detail with reference to the drawings. Note that, the following description of a preferred embodiment is merely exemplary in nature and is not intended to limit the invention, the application thereof, or the use thereof.

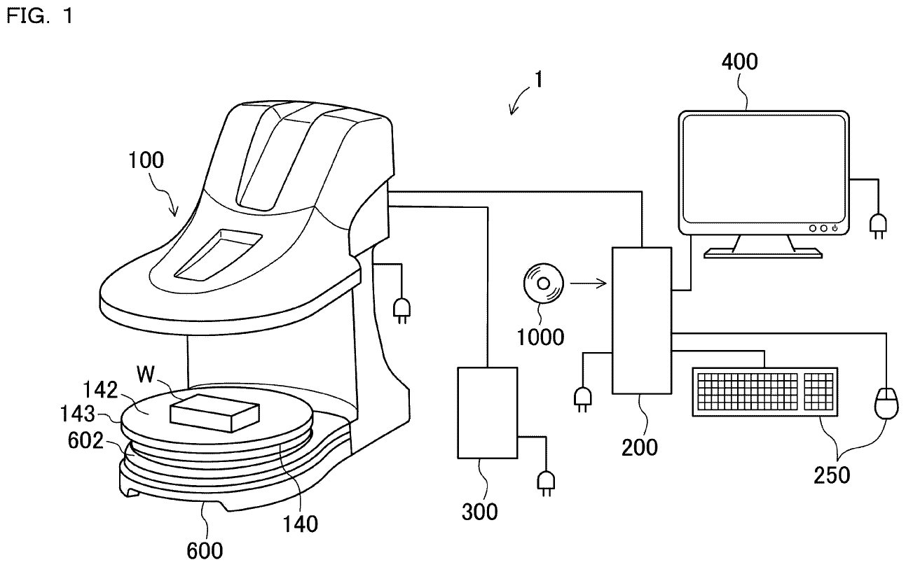

FIG. 1 is a diagram illustrating an overall configuration of a three-dimensional scanner 1 according to the embodiment of the invention. The three-dimensional scanner 1 is a device capable of acquiring three-dimensional data by measuring a shape of a workpiece (measurement object) W, converting the three-dimensional data into mesh data of the workpiece W, and outputting the mesh data. The three-dimensional scanner 1 can also convert the mesh data of the workpiece W into CAD data and output the CAD data, or convert the mesh data into surface data and output the surface data.

In the following description, when the shape of the workpiece W is measured, in acquiring coordinate information of a front surface of the workpiece W, the workpiece W is irradiated with measurement light of a predetermined pattern, and the coordinate information is acquired by using a signal obtained from reflected light reflected by the front surface of the workpiece W. For example, it is possible to use a measurement method using triangulation using a fringe projection image obtained from the reflected light by projecting the measurement light onto the workpiece W by using structured illumination as the measurement light of the predetermined pattern. However, in the invention, the principle and configuration for acquiring the coordinate information of the workpiece W are not limited thereto, and other methods can also be applied.

The three-dimensional scanner 1 includes a measurement unit 100 that measures the shape of the workpiece W, a pedestal 600 on which the workpiece W can be mounted, a controller 200, a light source unit 300, a display unit 400, and the like. The controller 200 may be incorporated in the measurement unit 100, the light source unit 300 may be incorporated in the measurement unit 100, or the display unit 400 may be incorporated in the measurement unit 100. In addition, the controller 200 and the light source unit 300 may be integrated, or the controller 200 and the display unit 400 may be integrated.

The three-dimensional scanner 1 performs the structured illumination on the workpiece W by the light source unit 300, captures the fringe projection image to generate a depth image having coordinate information, and can measure a three-dimensional dimension and shape of the workpiece W based on the depth image. The measurement using such fringe projection has an advantage that a measurement time can be shortened since three-dimensional measurement can be performed without moving the workpiece W or an optical system such as a lens in a Z direction (height direction).

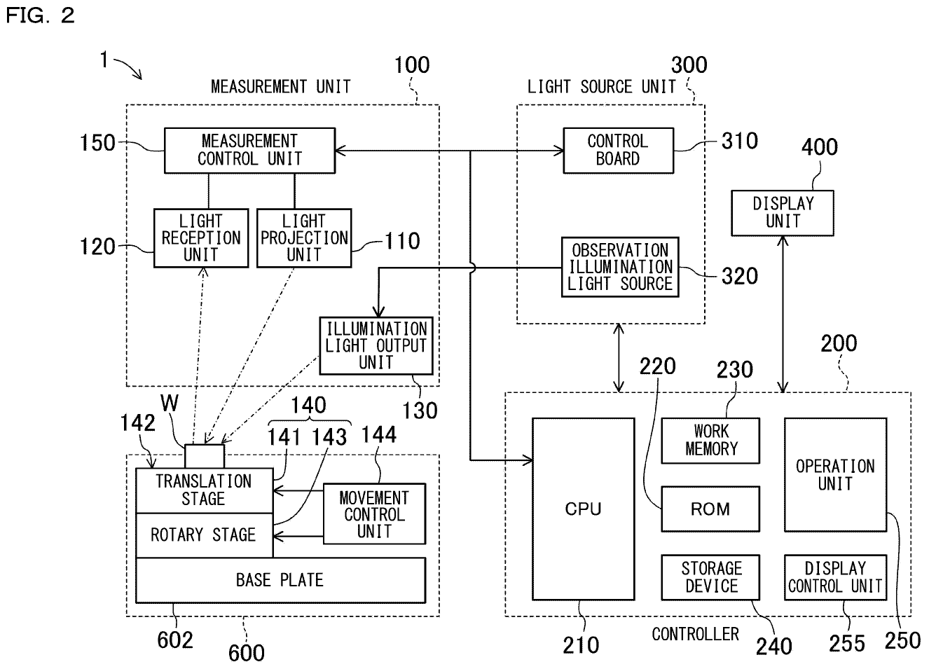

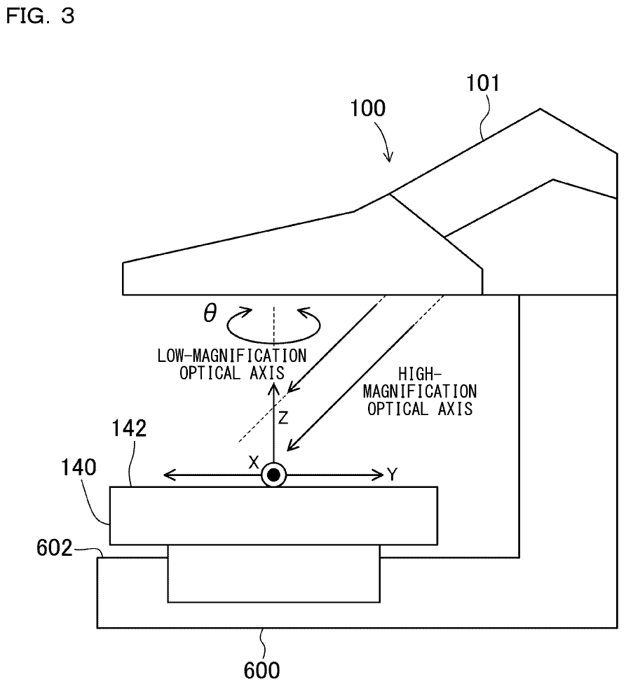

FIG. 2 illustrates a block diagram of the three-dimensional scanner 1 according to the embodiment of the invention. As illustrated in this drawing, the measurement unit 100 includes a pattern light projection unit (first light projection unit) 110 that projects pattern light for measurement onto the workpiece W, a light reception unit 120, a measurement control unit 150, and an illumination light output unit 130. The light projection unit 110 is a portion that irradiates the workpiece W mounted on a mounting unit 140 to be described later with the measurement light of the predetermined pattern. The mounting of the workpiece W on the mounting unit 140 is the same as the arrangement of the workpiece W on the mounting unit 140.

The light reception unit 120 is fixed in a posture tilted with respect to a mounting surface 142 of a rotary stage 143 to be described later. The light reception unit 120 receives the measurement light emitted by the light projection unit 110 and reflected by the workpiece W. When the measurement light is received as the reflected light from the workpiece W, the light reception unit 120 generates and outputs a first light reception signal for measurement indicating the amount of received measurement light. The light reception unit 120 can generate an observation image for observing the entire shape of the workpiece W by capturing the workpiece W mounted on the mounting unit 140. In this example, the illumination light output unit 130 is provided, but the workpiece W may be irradiated with uniform light from the light projection unit 110. In this case, the light projection unit 110 is a member that irradiates the workpiece W with the measurement light and the uniform light at different timings. The light reception unit 120 can also receive the uniform light emitted from the light projection unit 110 and output a second light reception signal for texture acquisition. For example, uniform light having the same wavelength as the measurement light can be emitted from a measurement light source, and a light reception signal including uniaxial color information can be output. Note that, although not illustrated, it is also possible to prepare calibrated first camera and second camera, acquire a shape by the first camera, and acquire texture information by the second camera. The texture information includes color information and luminance information of the workpiece W.

The light reception unit 120 according to the present embodiment includes a high-magnification light reception unit and a low-magnification light reception unit. The high-magnification light reception unit is a portion capable of capturing the workpiece W in an enlarged manner as compared with the low-magnification light reception unit. On the other hand, the low-magnification light reception unit is a light reception unit having a wider field of view range than the high-magnification light reception unit.

The pedestal 600 includes a base plate 602, the mounting unit 140, and a movement control unit (stage control unit) 144. The mounting unit 140 is supported on the base plate 602 of the pedestal 600. The movement control unit 144 is a portion that controls movement and rotation operations of the rotary stage 143 on which the workpiece W is mounted. The movement control unit 144 may be provided on the controller 200 side in addition to being provided on the pedestal 600 side.

The light source unit 300 is connected to the measurement unit 100. The light source unit 300 is a portion that generates the measurement light and supplies the measurement light to the measurement unit 100. The controller 200 is a portion that controls the measurement unit 100 and the like. The display unit 400 is connected to the controller 200, and is configured to display the image generated by the measurement unit 100 and to perform necessary setting, input, selection, and the like.

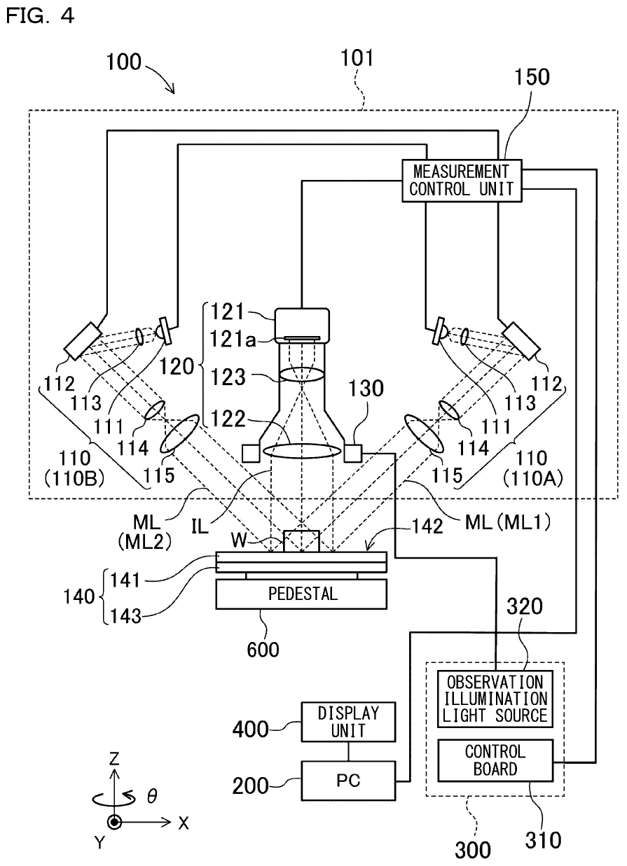

The mounting unit 140 includes the rotary stage 143 having a top surface on which the mounting surface 142 on which the workpiece W is mounted is formed. As illustrated in FIG. 4, two directions orthogonal to each other in the mounting surface 142 of the rotary stage 143 are defined as an X direction and a Y direction, and are indicated by arrows X and Y, respectively. A direction orthogonal to the mounting surface 142 of the mounting unit 140 is defined as a Z direction, and is indicated by an arrow Z. A direction of rotation about an axis parallel to the Z direction is defined as a θ direction, and is indicated by an arrow θ.

The mounting unit 140 includes the rotary stage 143 that rotates the mounting surface 142 about an axis extending in the Z direction, and a translation stage 141 that moves the mounting surface 142 in a horizontal direction (X direction and Y direction). The translation stage 141 includes an X-direction moving mechanism and a Y-direction moving mechanism. The rotary stage 143 has a θ-direction rotation mechanism. The mounting unit 140 may include a workpiece holding member (clamp or the like) that holds the workpiece W on the mounting surface 142. Further, the mounting unit 140 may include a tilt stage having a mechanism rotatable about an axis parallel to the mounting surface 142.

The movement control unit 144 controls the rotational movement of the rotary stage 143 and the translation of the translation stage 141 according to measurement conditions set by a measurement condition setting unit 261 to be described later. In addition, the movement control unit 144 controls a movement operation of the mounting unit 140 by a mounting movement unit based on a measurement region set by the measurement condition setting unit 261 to be described later.

The controller 200 includes a central processing unit (CPU) 210, a read only memory (ROM) 220, a work memory 230, a storage device (storage unit) 240, an operation unit 250, and the like. For example, a personal computer (PC) or the like can be used as the controller 200.

A configuration of the measurement unit 100 is illustrated in a block diagram of FIG. 4. The measurement unit 100 includes the light projection unit 110, the light reception unit 120, the illumination light output unit 130, the measurement control unit 150, and a body case 101 that houses these units. The light projection unit 110 includes a measurement light source 111, a pattern generation unit 112, and a plurality of lenses 113, 114, and 115. The light reception unit 120 includes a camera 121 and a plurality of lenses 122 and 123. In a case where measurement is performed at different magnifications by providing a plurality of light reception units, a light reception unit 120a including a camera 121 for low magnification and a lens for low magnification, and a light reception unit 120b including a camera 121 for high magnification and a lens for high magnification may be mounted. Note that, the invention is not limited to this configuration, and the magnification may be variable by switching between a plurality of lenses for one camera 121, or the magnification may be variable by providing a zoom lens for one camera 121.

The light projection unit 110 is arranged obliquely above the mounting unit 140. In the example illustrated in FIG. 4, the measurement unit 100 includes two light projection units 110, but the measurement unit 100 may include a plurality of light projection units 110. Here, a first measurement light projection unit 110A (right side in FIG. 4) capable of irradiating the workpiece W with first measurement light ML1 from a first direction and a second measurement light projection unit 110B (left side in FIG. 4) capable of irradiating the workpiece W with second measurement light ML2 from a second direction different from the first direction are provided. The first measurement light projection unit 110A and the second measurement light projection unit 110B are arranged symmetrically with respect to an optical axis of the light reception unit 120. Note that, although not illustrated, it is also possible to include three or more light projection units 110, or to relatively move the light projection unit 110 and the mounting unit 140 to project light onto the workpiece W in different illumination directions while using the common light projection unit 110. In addition, in the above example, the plurality of light projection units 110 are prepared and the light rays are received by the common light reception unit 120, but conversely, a plurality of light reception units 120 may be prepared for the common light projection unit 110, and the light rays may be received by the plurality of light reception units. Further, in this example, an irradiation angle of the illumination light projected by the light projection unit 110 with respect to the Z direction is fixed, but this may be variable.

Each of the first measurement light projection unit 110A and the second measurement light projection unit 110B includes, as the measurement light source 111, a first measurement light source and a second measurement light source. The measurement light source 111 is, for example, a halogen lamp that emits white light. The measurement light source 111 may be a light source that emits monochromatic light, for example, another light source such as a blue light emitting diode (LED) or an organic EL that emits blue light. The light (hereinafter, referred to as “measurement light”) emitted from the measurement light source 111 is appropriately condensed by the lens 113 and is then incident on the pattern generation unit 112.

A relative positional relationship among the light reception unit 120, the light projection units 110A and 110B, and the mounting unit 140 is determined such that central axes of the light projection units 110A and 110B and a central axis of the light reception unit 120 intersect each other at a position where the arrangement of the workpiece W on the mounting unit 140 and depths of field of the light projection unit 110 and the light reception unit 120 are appropriate. In addition, since a center of a rotation axis in the 0 direction coincides with the center axis of the light reception unit 120, when the mounting unit 140 rotates in the 0 direction, the workpiece W does not deviate from a field of view and rotates in the field of view about the rotation axis.

The pattern generation unit 112 reflects the light emitted from the measurement light source 111 so as to project the measurement light onto the workpiece W. The measurement light incident on the pattern generation unit 112 is converted into a preset pattern and preset intensity (brightness) and emitted. The measurement light emitted by the pattern generation unit 112 is converted into light having a diameter larger than an observable and measurable field of view of the light reception unit 120 by the plurality of lenses 114 and 115, and then the workpiece W on the mounting unit 140 is irradiated with the converted light.

The pattern generation unit 112 is a member capable of switching between a light projection state where the measurement light is projected onto the workpiece W and a non-light projection state where the measurement light is not projected onto the workpiece W. For such a pattern generation unit 112, for example, a digital micromirror device (DMD) or the like can be used. The pattern generation unit 112 using the DMD can be controlled by the measurement control unit 150 to be switchable between a reflection state where the measurement light is reflected on the optical path as the light projection state and a light shielding state where the measurement light is shielded as the non-light projection state.

Note that, in the above example, an example in which the DMD is used for the pattern generation unit 112 has been described, but the pattern generation unit 112 is not limited to the DMD in the invention, and other members can also be used. For example, liquid crystal on silicon (LCOS) may be used as the pattern generation unit 112. Alternatively, the amount of transmitted measurement light may be adjusted by using a transmissive member instead of a reflective member. In this case, the pattern generation unit 112 is arranged on the optical path of the measurement light to switch between a light projection state where the measurement light is transmitted and a light shielding state where the measurement light is shielded. For example, a liquid crystal display (LCD) can be used as the pattern generation unit 112. Alternatively, the pattern generation unit 112 may be formed by a projection method using a plurality of line LEDs, a projection method using a plurality of optical paths, an optical scanner method including a laser and a galvanometer mirror, an accordion fringe interferometry (AFI) method using interference fringes generated by superimposing beams divided by a beam splitter, a projection method using an actual grating and a moving mechanism including a piezo stage, a high-resolution encoder, and the like.

The light reception unit 120 is arranged above the mounting unit 140. The measurement light reflected upward from the mounting unit 140 by the workpiece W is collected and captured by the plurality of lenses 122 and 123 of the light reception unit 120, and then received by the camera 121.

The camera 121 is, for example, a charge coupled device (CCD) camera including an imaging element 121a. The imaging element 121a is, for example, a monochrome charge coupled device (CCD). The imaging element 121a may be another imaging element such as a complementary metal oxide semiconductor (CMOS) image sensor. In a color imaging element, since each pixel needs to correspond to light reception for red, green, and blue, measurement resolution is lower than that of a monochrome imaging element. Since a color filter needs to be provided in each pixel, sensitivity is lowered. Thus, in the present embodiment, a color image is acquired by adopting the monochrome CCD as the imaging element and causing the illumination light output unit 130 to be described later to emit illumination corresponding to each of RGB colors in a time division manner to capture an image. With such a configuration, it is possible to acquire a color image of a measurement object without lowering measurement accuracy. The illumination light output unit 130 is an example of a second light projection unit that irradiates the workpiece W with the illumination light. The illumination light can be uniform light.

Note that, the color imaging element may be used as the imaging element 121a. In this case, although the measurement accuracy and sensitivity are lower than those of the monochrome imaging element, it is not necessary to emit illumination corresponding to each of the RGB colors from the illumination light output unit 130 in a time division manner, and the color image can be acquired merely by emitting white light, and thus, an illumination optical system can be simply formed. An analog electric signal (hereinafter, referred to as a “light reception signal”) corresponding to the amount of received light is output from each pixel of the imaging element 121a to the measurement control unit 150.

An analog/digital converter (A/D converter) and a first-in first-out (FIFO) memory (both are not illustrated) are mounted on the measurement control unit 150. Light reception signals output from the camera 121 are sampled at a constant sampling period and converted into digital signals by the A/D converter of the measurement control unit 150 under the control of the light source unit 300. The digital signals output from the A/D converter are sequentially accumulated in the FIFO memory. The digital signals accumulated in the FIFO memory are sequentially transferred, as pixel data, to the controller 200.

The operation unit 250 of the controller 200 can include, for example, a keyboard, a pointing device, and the like. For example, a mouse, a joystick, or the like is used as the pointing device.

The ROM 220 of the controller 200 stores a system program and the like. The work memory 230 of the controller 200 includes, for example, a random access memory (RAM) and is used for processing various types of data. The storage device 240 includes a solid state drive, a hard disk drive, or the like. The storage device 240 stores a reverse engineering program. In addition, the storage device 240 is used to store various types of data such as pixel data (image data), setting information, and measurement conditions given from the measurement control unit 150. The measurement conditions include, for example, various settings set by a scanner module 260 to be described later when the shape of the workpiece W is measured, such as the setting (pattern frequency or pattern type) of the light projection unit 110 and a type (low-magnification light reception unit or high-magnification light reception unit) of the light reception unit 120. Further, the storage device 240 can also store luminance information, coordinate information, and attribute information every pixel constituting a measurement image.

The CPU 210 is a control circuit or a control element that processes a given signal or data, performs various arithmetic operations, and outputs an arithmetic operation result. In the present specification, the CPU means an element or a circuit that performs the arithmetic operation, and is not limited to a processor such as a CPU, an MPU, a GPU, or a TPU for a general-purpose PC regardless of a name, and is used in the sense of including a processor such as an FPGA, an ASIC, or an LSI, a microcomputer, or a chip set such as an SoC.

The CPU 210 generates image data based on the pixel data given from the measurement control unit 150. In addition, the CPU 210 performs various types of processing on the generated image data by using the work memory 230. For example, the CPU 210 generates measurement data representing the three-dimensional shape of the workpiece W included in the field of view of the light reception unit 120 at a specific position of the mounting unit 140 based on the light reception signal output from the light reception unit 120. The measurement data is the image itself acquired by the light reception unit 120, and for example, in a case where the shape of the workpiece W is measured by a phase shift method, a plurality of images constitute one piece of measurement data. Note that, the measurement data may be point cloud data that is a set of points having three-dimensional position information, and the measurement data of the workpiece W can be acquired from the point cloud data. The point cloud data is data expressed by an aggregate of a plurality of points having three-dimensional coordinates.

The movement control unit 144 determines whether or not to execute only the rotation operation of the rotary stage 143 or to execute both the rotation operation of the rotary stage 143 and the translation operation of the translation stage 141 based on the measurement data of at least a part of the workpiece W. As a result, an imaging range is automatically determined without the user's consciousness in accordance with an outer shape of the workpiece W, and thus, three-dimensional measurement becomes easy. Note that, after the translation stage 141 is moved in an XY direction, the movement control unit 144 can control the rotary stage 143 to rotate in a state where the movement in the XY direction is stopped, and thus, a shape around the workpiece W can also be acquired. Note that, scanning can also be performed by relatively moving and rotating the workpiece W with respect to the measurement unit 100 in a state where the measurement unit 100 is fixed.

The display unit 400 is a member for displaying the fringe projection image acquired by the measurement unit 100, the depth image generated based on the fringe projection image, a texture image captured by the measurement unit 100, various user interface screens, and the like. The display unit 400 includes, for example, an LCD panel or an organic electroluminescence (EL) panel. Further, a touch panel is used for the display unit 400, and thus, it can also be used as the operation unit 250. In addition, the display unit 400 can also display an image generated by the light reception unit 120.

The light source unit 300 includes a control board 310 and an observation illumination light source 320. A CPU (not illustrated) is mounted on the control board 310. The CPU of the control board 310 controls the light projection unit 110, the light reception unit 120, and the measurement control unit 150 based on a command from the CPU 210 of the controller 200. Note that, this configuration is an example, and other configurations may be used. For example, the control board may be omitted by controlling the light projection unit 110 and the light reception unit 120 by the measurement control unit 150 or controlling the light projection unit 110 and the light reception unit 120 by the controller 200. Alternatively, a power supply circuit for driving the measurement unit 100 may be provided in the light source unit 300.

The observation illumination light source 320 includes, for example, LEDs of three colors that emit red light, green light, and blue light. The luminance of the light emitted from each LED is controlled, and thus, light of any color can be generated from the observation illumination light source 320. Illumination light IL generated from the observation illumination light source 320 is output from the illumination light output unit 130 of the measurement unit 100 through a light guide member (light guide). Note that, as the observation illumination light source, other light sources such as a semiconductor laser (LD), a halogen light, and a HID can be appropriately used in addition to the LED. In particular, in a case where an element capable of performing capturing in color is used as the imaging element, a white light source can be used as the observation illumination light source.

The illumination light IL output from the illumination light output unit 130 irradiates the workpiece W with red light, green light, and blue light in a time division manner. As a result, it is possible to obtain a color texture image by combining texture images respectively captured by these RGB lights and display the texture image on the display unit 400.

A three-dimensional measurement program and an application for realizing a function of the three-dimensional scanner 1 by the controller 200 are installed on the controller 200. As a result, a three-dimensional measurement method according to the invention can be executed by using the three-dimensional scanner 1. The three-dimensional measurement method is a method for measuring a three-dimensional shape of the workpiece W, and is executed by a computer included in the controller 200. A three-dimensional measurement program for causing a computer to execute the three-dimensional measurement method can be recorded in a storage medium 1000. The storage medium 1000 may be, for example, an optical disk such as a CD-ROM or a DVD-ROM, or may be a semiconductor memory such as a memory card.

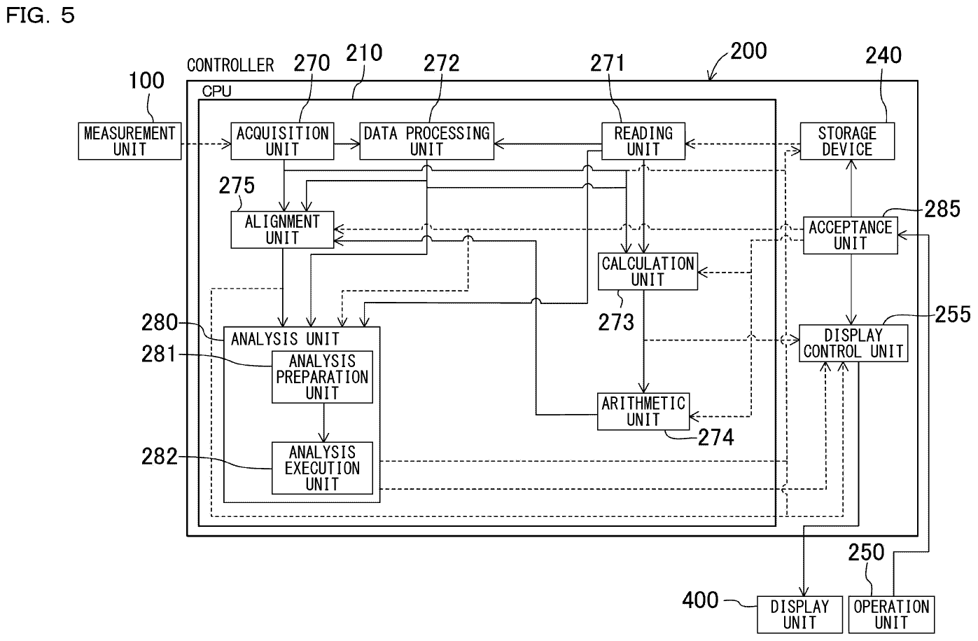

In the controller 200 on which the three-dimensional measurement program and the application are installed, the CPU 210, the ROM 220, the work memory 230, the storage device 240, and the like constitute the scanner module 260, a conversion module 270, an integration module 280, and an analysis module 290 illustrated in FIG. 5. In this embodiment, the scanner module 260, the conversion module 270, the integration module 280, and the analysis module 290 are divided into four modules, but any two or more of the modules 260, 270, 280, and 290 may be integrated to constitute one module. In addition, a part of each of the modules 260, 270, 280, and 290 may be incorporated in another module. That is, the configuration example illustrated in FIG. 5 is an example, and is not limited to the configuration example illustrated in FIG. 5.

The scanner module 260 is a portion that acquires image data of the workpiece W by measuring the shape of the workpiece W and creates mesh data of the workpiece W based on the image data. The conversion module 270 is a portion that converts the mesh data created by the scanner module 260 into CAD data. The CAD data is three-dimensional shape information constituted by an analytical curved surface and a free-form surface, and includes surface data, solid data, data used for design, and the like. The surface data is data of a shape surface including a free-form surface and an analytical curved surface, such as side surface data and plane data of a cylinder.

The integration module 280 is a portion that transmits signals and data from the scanner module 260 to the conversion module 270 and the analysis module 290, and transmits signals and data from the conversion module 270 to the scanner module 260. In this example, the module can execute a plurality of arithmetic processing in one unit, and can also be referred to as a functional unit, a functional block, or the like, for example.

The scanner module 260 includes, for example, the measurement condition setting unit 261, a scanner control unit 262, a point cloud acquisition unit 263a, a mesh data generation unit 263b, a scanner output unit 264, and the like. The measurement condition setting unit 261 is a portion for setting a measurement condition of the shape of the workpiece. The scanner control unit 262 is portion that controls the measurement unit 100 according to the measurement condition set by the measurement condition setting unit 261 to generate image data and acquires measurement data of the workpiece W based on the generated image data.

The point cloud acquisition unit 263a is a portion that acquires the point cloud data of the workpiece W based on the image data of the workpiece W acquired by the scanner control unit 262. The mesh data generation unit 263b is a portion that acquires the point cloud data acquired by the point cloud acquisition unit 263a, processes the acquired point cloud data, and converts the data into mesh data.

The scanner output unit 264 is a portion that outputs the mesh data created by the mesh data generation unit 263b and additional data to the conversion module 270. The additional data is, for example, data including at least one of the measurement condition and data calculated from the measurement data of the workpiece W.

The scanner module 260 controls the measurement unit 100, and generates conditions (measurement device model, measurement magnification, resolution, and the like) under which the shape of the workpiece W has been measured and Raw data (for example, image data) at the time of measurement together with three-dimensional data. The three-dimensional data is mesh data including a plurality of polygons, and can also be referred to as polygon data. The polygon is data including information specifying a plurality of points and information indicating a polygonal surface formed by connecting the points, and can include, for example, information specifying three points and information indicating a triangular surface formed by connecting the three points. The mesh data and the polygon data can also be defined as data expressed by an aggregate of a plurality of polygons.

In the conversion module 270, the mesh data is converted into CAD data, and conversion processing is determined based on the measurement condition and Raw data. Specifically, the conversion module 270 includes, for example, a data input unit 271, a processing parameter determination unit 272, a CAD conversion unit 273, a CAD output unit 274, and the like. The data input unit 271 is a portion that accepts the mesh data output from the scanner output unit 264 and the additional data. The processing parameter determination unit 272 is a portion that determines a processing parameter when the mesh data is converted into the CAD data according to the additional data accepted by the data input unit 271. The CAD conversion unit 273 is a portion that converts the mesh data into the CAD data according to the processing parameter determined by the processing parameter determination unit 272. The CAD output unit 274 is a portion that outputs the CAD data converted by the CAD conversion unit 273.

The analysis module 290 of the three-dimensional scanner 1 is a module that generates combined three-dimensional data of the workpieces W by generating pieces of three-dimensional data of workpieces W arranged in different arrangement postures and combining the pieces of three-dimensional data. The analysis module 290 includes, for example, a data acquisition unit 291 that acquires the three-dimensional data of the workpiece W mounted on the rotary stage 143. The user can mount the workpiece W on the rotary stage 143 in any posture. For example, in a case where three-dimensional shapes of a front side and a back side of the workpiece W are acquired, the three-dimensional data can be acquired by mounting the workpiece W on the rotary stage 143 in an arrangement posture in which the front side of the workpiece W faces upward to acquire the three-dimensional data and then mounting the workpiece W on the rotary stage 143 in an arrangement posture in which the back side of the workpiece W faces upward to acquire the three-dimensional data. In addition, in a case where a three-dimensional shape of a side surface of the workpiece W is acquired, the three-dimensional data can be acquired by mounting the workpiece W on the rotary stage 143 in an arrangement posture in which the side surface of the workpiece W faces upward. For example, the arrangement posture in which the front side of the workpiece W faces upward can be set as a first arrangement posture, and the arrangement posture in which the back side of the workpiece W faces upward can be set as a second arrangement posture. In addition, the arrangement posture in which the side surface of the workpiece W faces upward may be a third arrangement posture. The definition of the arrangement posture is an example, and the arrangement postures may be different from each other. For example, the first arrangement posture, the second arrangement posture, and the third arrangement posture can be defined in accordance with the shape of the workpiece W, a range in which three-dimensional data is desired to be acquired, and the like. In addition, a fourth arrangement posture and a fifth arrangement posture may be defined, and the number of arrangement postures is not particularly limited.

The data acquisition unit 291 acquires first three-dimensional data that is three-dimensional data of the workpiece W arranged on the rotary stage 143 in the first arrangement posture and second three-dimensional data that is three-dimensional data of the workpiece W arranged on the rotary stage 143 in the second arrangement posture. Similarly, the data acquisition unit 291 also acquires third three-dimensional data that is three-dimensional data of the workpiece W arranged on the rotary stage 143 in the third arrangement posture, fourth three-dimensional data that is three-dimensional data of the workpiece W arranged on the rotary stage 143 in the fourth arrangement posture, and the like.

The data acquisition unit 291 acquires three-dimensional data measured by the scanner module 260. The three-dimensional data acquired by the data acquisition unit 291 includes shape information and texture information of the workpiece W, and the data acquisition unit 291 acquires textured shape data. Accordingly, the data acquisition unit 291 acquires the first three-dimensional data that is the three-dimensional data including the shape information and the texture information of the workpiece W arranged in the first arrangement posture, and the second three-dimensional data that is the three-dimensional data including the shape information and the texture information of the workpiece W arranged in the second arrangement posture.

The data acquisition unit 291 receives the light reception signal generated by the light reception unit 120 of the measurement unit 100, generates a live image of the workpiece W based on the received light reception signal, and acquires the generated live image.

The mesh data generation unit 263b generates first mesh data that is mesh data of the workpiece W arranged in the first arrangement posture and second mesh data that is mesh data of the workpiece W arranged in the second arrangement posture. Similarly, the mesh data generation unit 263b can also generate third mesh data that is mesh data of the workpiece W arranged in the third arrangement posture and fourth mesh data that is mesh data of the workpiece W arranged in the fourth arrangement posture.

In a case where the mesh data generation unit 263b generates the mesh data, the data acquisition unit acquires, as the first three-dimensional data and the second three-dimensional data, the first mesh data and the second mesh data generated by the mesh data generation unit 263b. Similarly, the third mesh data and the fourth mesh data can also be acquired.

For example, the three-dimensional data (first three-dimensional data) of the workpiece W arranged in the first arrangement posture can be stored in the storage device 240. In this case, a reading unit 292 included in the analysis module 290 reads the first three-dimensional data stored in the storage device 240. Similarly, the second three-dimensional data, the third three-dimensional data, and the fourth three-dimensional data can be stored in the storage device 240. In this case, the reading unit 292 reads the second three-dimensional data, the third three-dimensional data, and the fourth three-dimensional data from the storage device 240.

In a case where there is the CAD data of the workpiece W, the CAD data of the workpiece W can be stored in the storage device 240. In this case, the reading unit 292 reads the CAD data stored in the storage device 240 from the storage device 240.

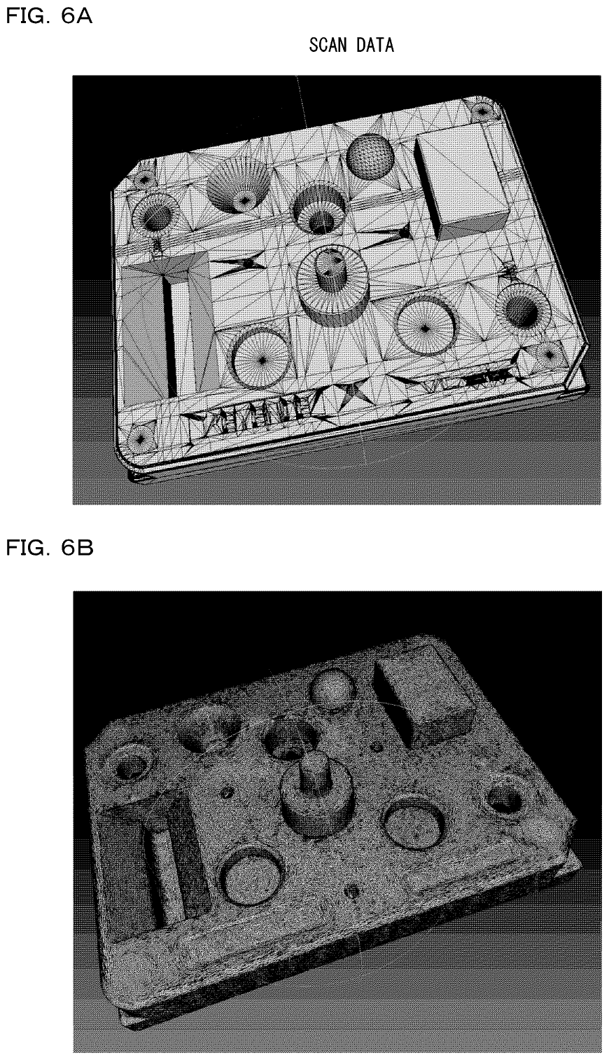

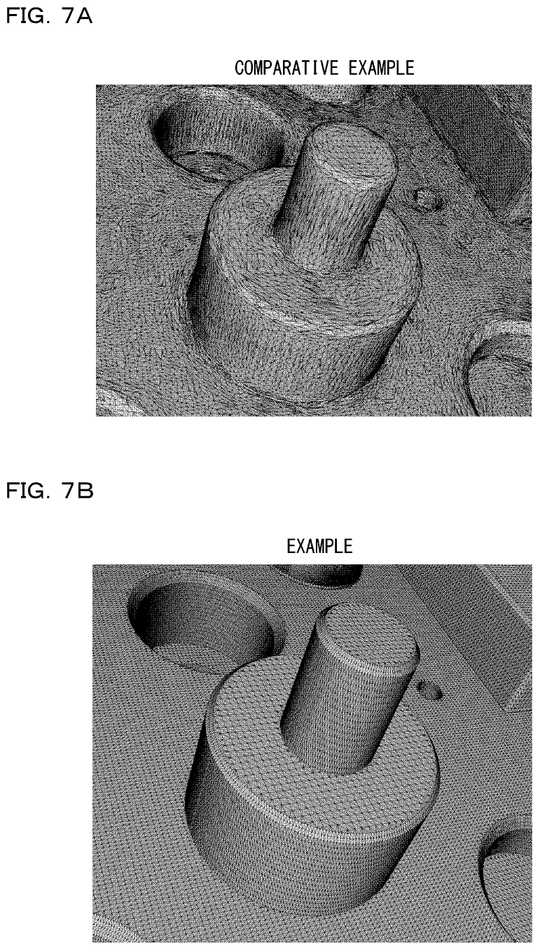

Hereinafter, scan processing in a case where there is no CAD data of the workpiece W and scan processing in a case where there is the CAD data of the workpiece W will be described. FIG. 6 illustrates an example of the scan processing in a case where there is no CAD data of the workpiece W. Before or after the start of this flow and before proceeding to step SA1, the workpiece W is mounted on the rotary stage 143 in the first arrangement posture. In step SA1, scanning of the workpiece W is started. In step SA2, the measurement unit 100 scans the workpiece W arranged in the first arrangement posture. For example, in a case where the workpiece W is arranged such that the front side of the workpiece W faces upward, since the back side of the workpiece W cannot be scanned, the scan in step SA2 is referred to as “one-side scan”. FIG. 7 illustrates a user interface screen 700 displayed at the start of measurement. The user interface screen 700 is generated by the controller 200 and displayed on the display unit 400.

A live image display region 701 and a model display region 702 are provided on the user interface screen 700. In the live image display region 701, the live image generated by the data acquisition unit 291 is displayed. In the live image, the rotary stage 143 and the workpiece W mounted on the rotary stage 143 are displayed. In addition, the measurement unit 100 can also be referred to as a scan head, and the scan head includes the light projection unit 110, the light reception unit 120, the illumination light output unit 130, and the measurement control unit 150. The display control unit 255 can also display the scan head and the workpiece W on the display unit 400. Such display is effective, for example, in a case where the workpiece W is arranged on any table and the workpiece W is scanned from different angles by moving the scan head side.

In step SA2, the light projection unit 110 of the measurement unit 100 irradiates the workpiece W arranged in the first arrangement posture with the measurement light. The light reception unit 120 of the measurement unit 100 receives the measurement light reflected by the workpiece W. The light reception signal output from the light reception unit 120 is received by the point cloud acquisition unit 263a, and first point cloud data of the workpiece W is generated. The mesh data generation unit 263b acquires the first point cloud data acquired by the point cloud acquisition unit 263a, processes the acquired first point cloud data, and converts the first point cloud data into the first mesh data. Note that, here, the processing of the point cloud data is thinning of the point cloud, removal of the point cloud outside the measurement region, removal of a noise point cloud, and the like. In step SA3, the first mesh data obtained by the processing in step SA2 is acquired as the first three-dimensional data. The first three-dimensional data is stored in the work memory 230 or the storage device 240. A model of the workpiece W based on the first three-dimensional data is displayed together with a model of the rotary stage 143 in the model display region 702 of the user interface screen 700 illustrated in FIG. 7. The user interface screen 700 is generated by the display control unit 255 included in the controller 200 and displayed on the display unit 400.

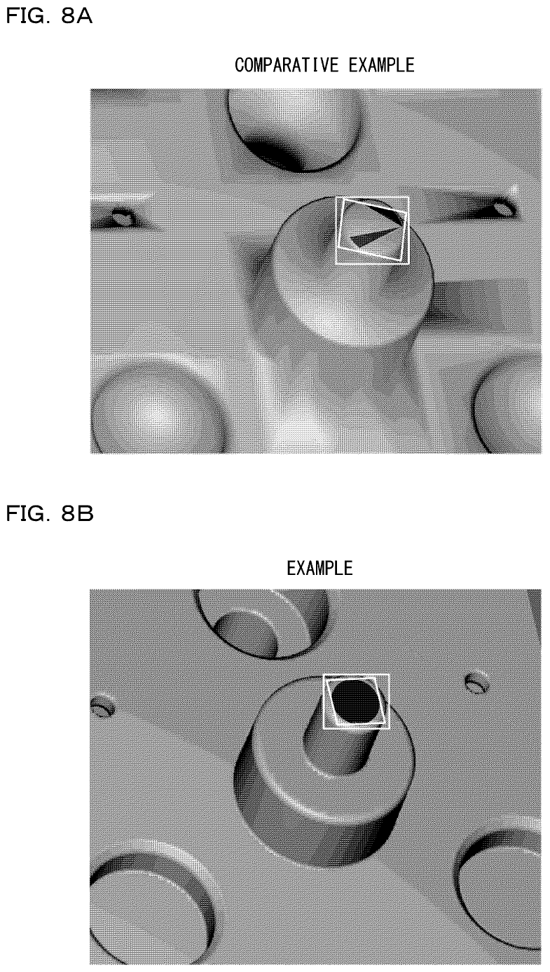

In step SA4, the three-dimensional scanner 1 calculates an evaluation value and proposes a posture candidate. The evaluation value in step SA4 is an example of an evaluation index to be described later. When the user operates a posture suggestion button 702a in the model display region 702, the controller 200 detects an operation thereof. Then, as illustrated in FIG. 8, the display control unit 255 generates a candidate display region 703 in which a next scannable posture candidate is displayed, and displays the generated candidate display region on the user interface screen 700. The user can select the posture candidate in step SA5 on the user interface screen 700.

When the three-dimensional scanner 1 proposes the posture candidate, the posture candidate is calculated before evaluation value calculation. That is, as illustrated in FIG. 5, the analysis module 290 includes a posture calculation unit 293. The posture calculation unit 293 is a portion that calculates an arrangement posture different from the first arrangement posture based on the first three-dimensional data acquired by the data acquisition unit 291, and specifically, calculates a recommended arrangement posture (hereinafter, also simply referred to as “arrangement posture”) different from the first arrangement posture based on the three-dimensional data read from the work memory 230 or the storage device 240 by the reading unit 292. The display control unit 255 overlaps and displays the recommended arrangement posture calculated by the posture calculation unit 293 on the live image acquired by the data acquisition unit 291.

When the arrangement posture different from the first arrangement posture is calculated, the posture calculation unit 293 first specifies the first arrangement posture of the workpiece W based on the first three-dimensional data. The first arrangement posture is specified, and thus, the posture calculation unit 293 can calculate the arrangement posture different from the first arrangement posture. A distance between the measurement unit 100 and the workpiece may be set based on a focal length of the lens of the measurement unit 100. In the present embodiment, since the measurement unit 100 includes the rotary stage 143, for example, the posture calculation unit 293 can calculate a plurality of arrangement postures by virtually rotating the first three-dimensional data about a rotation axis of the rotary stage 143. When the first three-dimensional data is rotated, the first three-dimensional data may not be rotated once, and may be rotated at a rotation angle of less than 360°.

In addition, in a case where the workpiece W is large, there is also a case where scanning is performed by translating the measurement unit 100 with respect to the workpiece W multiple times. Whether or not the measurement unit is moved in parallel with the workpiece a plurality of times to perform scanning can be determined by the analysis module 290 based on whether or not the first three-dimensional data exceeds a measurable range (length, width, and height) of the measurement unit 100. In a case where the first three-dimensional data exceeds the measurable range of the measurement unit 100, it can be determined that scanning is performed by translating the measurement unit 100 with respect to the workpiece W multiple times, and conversely, in a case where the first three-dimensional data is within the measurable range of the measurement unit 100, it can be determined that scanning is performed without translating the measurement unit 100 multiple times.

In a case where scanning is performed by translating the measurement unit 100 with respect to the workpiece W multiple times, a measurement range of the measurement unit 100 overlaps a certain level or more, and the measurement unit 100 is virtually arranged in a plurality of directions based on a center point translated such that the workpiece is most included. Note that, although a method for virtually moving the measurement unit 100 has been described, the invention is not limited thereto, and the workpiece may be moved and rotated.

The analysis module 290 includes an arithmetic unit 294. The arithmetic unit 294 calculates a relative position posture of the recommended arrangement posture with respect to the first arrangement posture. In a case where a plurality of arrangement postures are calculated by the posture calculation unit 293, the arithmetic unit 294 calculates a relative position posture with respect to the first arrangement posture for each of the plurality of arrangement postures. For example, the arithmetic unit 294 calculates a conversion expression for converting a relative positional relationship between the first arrangement posture and the recommended arrangement posture. The arithmetic unit 294 applies the conversion expression to the three-dimensional data of the first arrangement posture to convert the first arrangement posture into the recommended arrangement posture.

As the arrangement posture different from the first arrangement posture, the posture calculation unit 293 can also calculate the candidate posture based on a size of a contact area with the mounting surface 142 in each of the plurality of arrangement postures. When the contact area with the mounting surface 142 is too small, it may be difficult to mount the workpiece W on the mounting surface 142. However, when the arrangement posture is calculated, it is possible to stabilize the workpiece W when the workpiece W is mounted on the mounting surface 142 by calculating the arrangement posture capable of securing a predetermined or more contact area with the mounting surface 142. Although FIG. 8 illustrates an example in which four arrangement postures are calculated, the number of arrangement postures calculated by the posture calculation unit 293 is not limited to four, and may be one or any number of two or more.

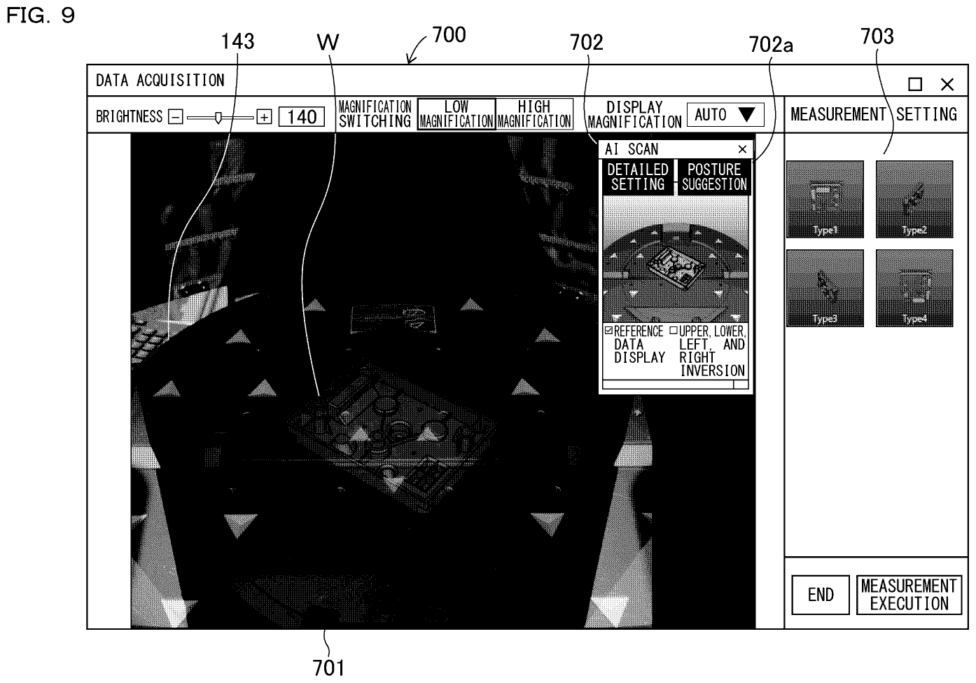

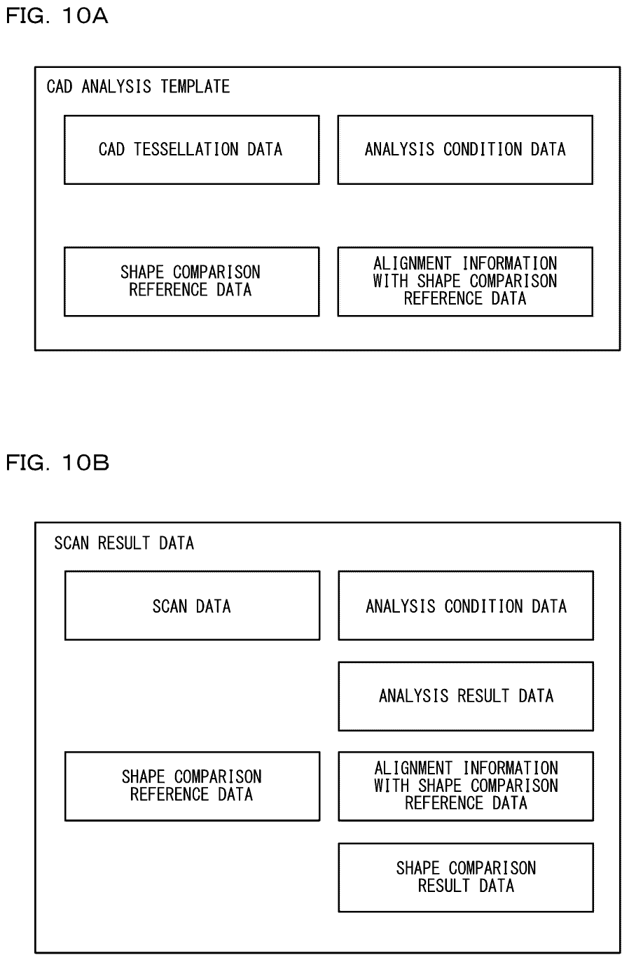

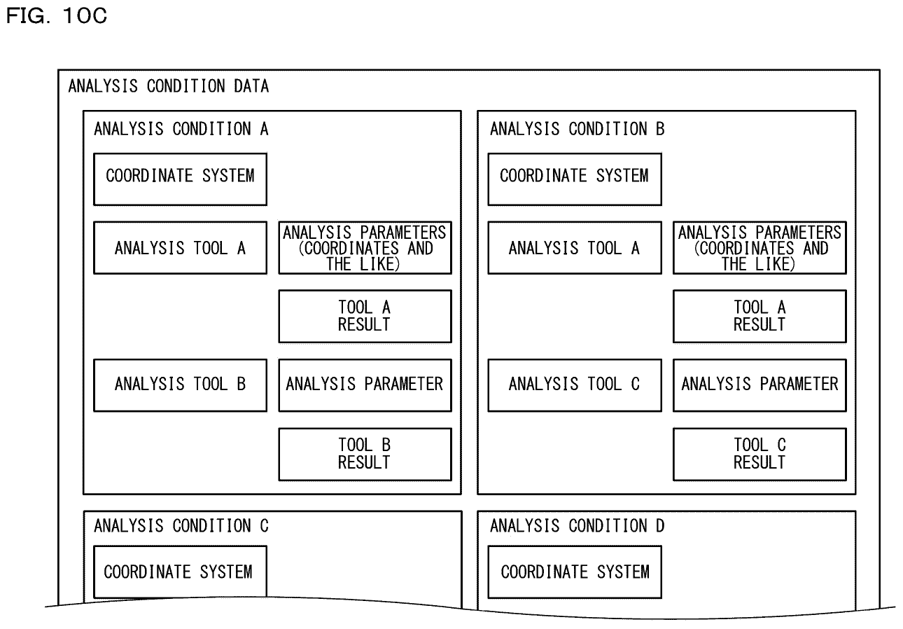

FIG. 9 illustrates a user interface screen 710 displayed when selection of the posture candidate is accepted, and is generated by the display control unit 255 and displayed on the display unit 400. A model display region 711 in which a model of the workpiece W based on the first three-dimensional data is displayed and a candidate display region 712 are provided on the user interface screen 710. In the candidate display region 712, four arrangement postures calculated by the posture calculation unit 293 are displayed. The arrangement postures are displayed in the candidate display region 712, and thus, it is possible to present a next scannable arrangement posture to the user.

An evaluation index display region 712a that displays an evaluation index indicating whether or not the arrangement posture of the workpiece presented to the user is an arrangement posture suitable for next scan is provided in the candidate display region 712. The evaluation index display region 712a is also generated by the display control unit 255 and displayed on the display unit 400.

The evaluation index is an index based on the amount of additional data to be added to the first three-dimensional data by performing the next scan and the amount of overlap region between the three-dimensional data acquired by performing the next scan and the first three-dimensional data. That is, the analysis module 290 includes an overlap region estimation unit 295 and an additional data amount estimation unit 296. The overlap region estimation unit 295 is a portion that estimates an overlap region between the three-dimensional data to be acquired by the data acquisition unit 291 in a state of being arranged in the arrangement posture calculated by the posture calculation unit 293 and the first three-dimensional data acquired by the data acquisition unit 291. The overlap region estimation unit 295 can also estimate a degree of feature based on a distribution of points in the overlap region.

An example of a method for estimating the overlap region by the overlap region estimation unit 295 will be described. Here, in a case where there is three-dimensional CAD data of the workpiece W, it is possible to further estimate, as the overlap region, an outermost surface when the three-dimensional CAD data is projected with respect to an outermost surface when the first three-dimensional data acquired by the data acquisition unit 291 is projected. However, as in the flowchart illustrated in FIG. 6, in a case where there is no three-dimensional CAD data of the workpiece W, since estimation based on the three-dimensional CAD data cannot be performed, a front surface of the existing first three-dimensional data is used as the overlap region as it is. In a case where the workpiece W has a complicated shape, there is a possibility that the front surface of a part of the existing first three-dimensional data is hidden by second and subsequent additional scans. In a case where there is the three-dimensional CAD data, the overlap region can be estimated in consideration of the influence of the front surface of a part of the existing first three-dimensional data being hidden, but in a case where there is no three-dimensional CAD data, the influence cannot be considered. However, in a case where the workpiece has a shape close to a convex polygon, there is no influence of the front surface of a part of the existing first three-dimensional data being hidden, and a substantially good result can be obtained. Therefore, the goodness of the overlap region can be determined by evaluating an area of the overlap region (the amount of overlap region) and the degree of feature. The degree of feature is obtained by analyzing the distribution of points in the overlap region. Specifically, the dispersion of the coordinates or the normal of the point can be used as the evaluation value.

Further, it is also necessary to consider whether or not the workpiece W can be arranged on the mounting surface 142 of the rotary stage 143 in the arrangement posture calculated by the posture calculation unit 293 at the time of actual measurement. In a case where the measurement unit 100 side moves with respect to the workpiece W, the analysis module 290 may perform collision determination between three-dimensional shapes of the measurement unit 100 and the pedestal 600 and the three-dimensional CAD data or the first three-dimensional data of the workpiece in a computer graphics space.

In addition, of course, since the workpiece W cannot be arranged below an installation surface on which the measurement unit 100 is installed, the analysis module 290 performs the collision determination with the installation surface (Z coordinate <0). In addition, since it is difficult to arrange the measurement unit 100 at an angle from directly above the workpiece or at a low angle with respect to the workpiece, the analysis module 290 can evaluate “ease of arrangement” according to an arrangement angle of the measurement unit 100.

In a case where the workpiece W is moved and rotated, the analysis module 290 also determines the ease of arrangement of the workpiece W on the mounting surface 142. The analysis module 290 calculates the three-dimensional data in the arrangement posture calculated by the posture calculation unit 293 or an area of a bottom surface when the three-dimensional data is approximated by a convex polygon, and determines that the larger the calculated area of the bottom surface is, the more stable the arrangement on the mounting surface 142 can be performed. In addition, in a case where there is the three-dimensional CAD data of the workpiece W, the analysis module 290 acquires coordinates of a center of gravity and a center point of the bottom surface, and calculates the distance between the center of gravity and the center point of the bottom surface. The analysis module 290 can determine the ease of arrangement of the workpiece W based on a distance between the center of gravity point and the center point of the bottom surface.

Next, the amount of additional data will be described. The additional data amount estimation unit 296 is a portion that estimates the amount of additional data to be added to the first three-dimensional data by acquiring the three-dimensional data by the data acquisition unit 291 in a state where each of the plurality of arrangement postures calculated by the posture calculation unit 293 is arranged in one arrangement posture. The additional data amount estimation unit 296 can move the first three-dimensional data so as to have each arrangement posture and estimate the amount of additional data based on an orientation of a normal vector after movement, and for example, can estimate the amount of additional data based on a positional relationship between the normal vector after movement from a predetermined viewpoint and a line-of-sight direction of the measurement unit 100. For example, an inner product of the normal vector after movement from the predetermined viewpoint and the line-of-sight direction of the measurement unit 100 is calculated, and thus, three-dimensional data facing the measurement unit 100 is specified, and it is estimated that the larger the number of pieces of three-dimensional data facing the measurement unit 100, the larger the amount of additional data.

An example of a method for estimating the amount of additional data by the additional data amount estimation unit 296 will be described. Assuming that scanning is performed with the posture candidate calculated by the posture calculation unit 293, the amount of additional data is obtained by estimating how much additional data can be acquired for the already acquired first three-dimensional data (this can also be referred to as “useable footage ratio”). Here, in a case where there is the three-dimensional CAD data of the workpiece W, a point that is present in the three-dimensional CAD data but is not present in the first three-dimensional data becomes additional data, and the amount of additional data increases as the number of points increases.

However, as in the flowchart illustrated in FIG. 6, in a case where there is no three-dimensional CAD data of the workpiece W, since the estimation based on the three-dimensional CAD data cannot be performed, the point cloud included in the first three-dimensional data is analyzed, and the number of points where the back side of the scanned surface is visible is set as the additional data. This is because the back surface is not visible in a completely scanned object, and thus a portion where the back surface is visible can be determined to be an unscanned portion.

The back surface of the workpiece W can be detected by detecting that the normal of the point included in the first three-dimensional data is directed in a direction opposite to the measurement unit 100. With this detection processing, it is possible to estimate the amount of additional data in a case where there is no three-dimensional CAD data of the workpiece W. Note that, the analysis module 290 can calculate a percentage of a scanned region of the workpiece W or a region requiring the remaining scanning based on an area of the already scanned region and the amount of additional data at the time of scanning in each direction. It is also possible for the analysis module 290 to automatically determine scan completion in a case where the scanned region exceeds a certain percentage. Either of the order of the estimation of the overlap region and the estimation of the amount of additional data may precede.

After the overlap region and the amount of additional data are estimated for each arrangement posture as described above, an evaluation unit 299 included in the analysis module 290 calculates the evaluation index. When the evaluation index is calculated, the evaluation index can be calculated based on, for example, the following expression. Evaluation index=(area of overlap region)×(amount of additional data)×(dispersion of points in overlap region)×(ease of arrangement)

As described above, the evaluation unit 299 calculates the evaluation index in each of the plurality of arrangement postures based on the amount of additional data in each of the plurality of arrangement postures calculated by the posture calculation unit 293 and the amount of overlap region, and calculates a comprehensive evaluation index based on each evaluation index. Note that, in a case where the texture information is used, integration, average, maximum, median, and the like of texture feature amounts based on local contrast or differential values of the texture information may be incorporated.

The display control unit 255 displays the calculated evaluation index in a numerical form or a graph form on the display unit 400. FIG. 9 illustrates a case where the evaluation index is displayed in a graph form in the evaluation index display region 712a. When the user performs an operation to select any one of the arrangement postures displayed in the candidate display region 712, the analysis module 290 specifies the selected arrangement posture. The display control unit 255 displays the evaluation index of the arrangement posture specified by the analysis module 290 in the evaluation index display region 712a in a graph form. When the user selects another arrangement posture, the display control unit 255 displays the evaluation index of the arrangement posture in the evaluation index display region 712a. As described above, since the display control unit 255 can display the evaluation index in each of the plurality of arrangement postures calculated by the posture calculation unit 293 on the display unit 400, in a case where the plurality of arrangement postures are presented, the user can obtain the evaluation index of each arrangement posture.

The display form of the evaluation index may not be the graph form illustrated in FIG. 9, but may be a numerical form displayed as a numerical value, or a display form combining the graph form and the numerical form. In addition, the display control unit 255 may display, on the display unit 400, each of the evaluation index based on the amount of additional data estimated by the additional data amount estimation unit 296 and the evaluation index based on the amount of overlap region estimated by the overlap region estimation unit 295. In this case, the analysis module 290 calculates a first evaluation index based on the amount of additional data estimated by the additional data amount estimation unit 296, and separately calculates a second evaluation index based on the amount of overlap region estimated by the overlap region estimation unit 295. The display control unit 255 may display only the first evaluation index on the display unit 400 in a graph form or a numerical form, may display only the second evaluation index on the display unit 400 in a graph form or a numerical form, or may display the first evaluation index and the second evaluation index separately on the display unit 400 in a graph form or a numerical form.

The analysis module 290 includes a specifying unit 297 that specifies one candidate posture from among the plurality of arrangement postures calculated by the posture calculation unit 293 based on the evaluation index. Specifically, the specifying unit 297 acquires the evaluation index for each of the plurality of arrangement postures. The specifying unit 297 specifies an arrangement posture of a highest evaluation index among the plurality of acquired evaluation indexes. Since the evaluation index is an index based on the amount of additional data estimated by the additional data amount estimation unit 296 and the amount of overlap region estimated by the overlap region estimation unit 295, the specifying unit 297 specifies one candidate posture based on the amount of additional data and the amount of overlap region. When one candidate posture is specified, the specifying unit 297 may specify one candidate posture based on the amount of additional data, the amount of overlap region, and the shape of the overlap region estimated by the overlap region estimation unit 295. For example, when the overlap region includes an irregularity shape, since alignment accuracy is higher than that of an overlap region having a flat shape, in the case of the overlap region including a recess portion or a protrusion portion, the evaluation index can be enhanced as compared with the flat overlap region.

When the specifying unit 297 identifies one candidate posture, the display control unit 255 displays one candidate posture specified by the specifying unit 297 on the display unit 400. The candidate posture displayed on the display unit 400 is an arrangement posture of the workpiece recommended by the three-dimensional scanner 1 to the user. Accordingly, the user can confirm an appropriate arrangement posture by viewing the display unit 400.

In step SA6 of FIG. 6, the user determines whether or not the candidate posture displayed on the display unit 400 is a desired posture. Since the arrangement posture is specified based on the evaluation index, since the amount of additional data is large, and the amount of overlap region is also large, it is considered that accurate combined three-dimensional data can be obtained by arranging the workpiece in this arrangement posture. However, since the specifying unit 297 specifies the arrangement posture only based on the evaluation index, a region of high interest of the user (a region in which high-accuracy three-dimensional data is desired) is not necessarily specified. Thus, in the three-dimensional scanner 1 of the present embodiment, the plurality of arrangement postures are presented to the user together with the evaluation indexes, and the user can select an arrangement posture having a relatively high evaluation index and most suitable for the user's interest from among the plurality of presented arrangement postures. Specifically, the analysis module 290 includes an acceptance unit 298 that accepts a selection operation or an adjustment operation of the arrangement posture by the user. For example, when the user performs an operation to select a desired arrangement posture from among the arrangement postures displayed in the candidate display region 712 of the user interface screen 710 illustrated in FIG. 9, a selected operation input is accepted by the acceptance unit 298. The display control unit 255 displays the arrangement posture accepted by the acceptance unit 298 in the candidate display region 712.

In addition, in step SA7, the candidate posture displayed on the display unit 400 can be adjusted. Specifically, the acceptance unit 298 accepts an operation input by the user for adjusting one candidate posture specified by the specifying unit 297. The user operates the operation unit 250 in the computer graphics space to adjust a positional relationship between the measurement unit 100 and the workpiece W. For example, the workpiece W in the candidate posture is moved horizontally, moved in a height direction, or rotated. When the adjustment of the candidate posture by the user is completed, the processing proceeds to step SA8, and the posture calculation unit 293 specifies the arrangement posture for which the adjustment is completed, the overlap region estimation unit 295 estimates the amount of overlap region between the three-dimensional data and the first three-dimensional data acquired by the data acquisition unit 291 in the arrangement posture for which the adjustment is completed, and the additional data amount estimation unit 296 estimates the additional data amount. The analysis module 290 newly calculates an evaluation index based on the estimated amount of overlap region and the estimated amount of additional data and presents the evaluation index to the user. As a result, in a case where the region of high interest of the user is scanned, the user can determine whether or not the posture is likely to succeed in alignment with the first three-dimensional data. Note that, the evaluation value calculation and the posture candidate proposal in step SA4 and the selection of the posture candidate in step SA5 may be skipped, and the posture calculation unit 293 may specify the arrangement posture for which the adjustment of the candidate posture by the user is completed in step SA7.

In step SA9, the analysis module 290 generates a workpiece (model) of the computer graphics in the determined arrangement posture. The display control unit 255 superimposes the workpiece of the computer graphics generated by the analysis module 290 on the live image acquired by the data acquisition unit 291 and displays the superimposed image on the display unit 400. The workpiece of the computer graphics is translucent, but may be opaque.

In step SA10, the user mounts the workpiece W on the mounting surface 142 at a temporary position. Then, the workpiece W is captured together with the mounting surface 142 by the light reception unit 120, and the live image including the workpiece W is acquired by the data acquisition unit 291 and displayed on the display unit 400. While viewing the live image on the display unit 400, the user moves or rotates an actual workpiece W until the actual workpiece W mounted on the mounting surface 142 overlaps the workpiece of the computer graphics.

In step SA11, the user determines whether or not the actual workpiece W mounted on the mounting surface 142 is mounted so as to overlap the workpiece of the computer graphics. In a case where the actual workpiece W mounted on the mounting surface 142 cannot be mounted so as to overlap the workpiece of the computer graphics, the processing proceeds to step SA5, and another arrangement posture is selected. In a case where the actual workpiece W is mounted so as to overlap the workpiece of the computer graphics, since the workpiece W is in the second arrangement posture, the processing proceeds to step SA12, and the measurement unit 100 scans the workpiece W arranged in the second arrangement posture.

In step SA12, the light projection unit 110 of the measurement unit 100 irradiates the workpiece W arranged in the second arrangement posture with the measurement light. The light reception unit 120 of the measurement unit 100 receives the measurement light reflected by the workpiece W. The light reception signal output from the light reception unit 120 is received by the point cloud acquisition unit 263a, and second point cloud data of the workpiece W is generated. The mesh data generation unit 263b acquires the second point cloud data acquired by the point cloud acquisition unit 263a, processes the acquired second point cloud data, and converts the data into second mesh data. In step SA12, the second mesh data obtained by the processing in step SA12 is acquired as the second three-dimensional data (step SA13). The second three-dimensional data is stored in the storage device 240.

In step SA14, an alignment unit 290A included in the analysis module 290 aligns the first three-dimensional data (three-dimensional data of the workpiece arranged in the first arrangement posture) acquired by the data acquisition unit 291 and the second three-dimensional data based on the relative positional relationship calculated by the arithmetic unit 294. At the time of this alignment, an overlap region extracted by an extraction unit 290B included in the analysis module 290 is used. The extraction unit 290B is a portion that extracts an overlap region between the three-dimensional data converted into the recommended arrangement posture by the arithmetic unit 294 and the three-dimensional data arranged in the second arrangement posture. The extraction unit 290B can extract the overlap region by using, for example, the normal vector of the three-dimensional data and the color information of the workpiece. That is, the alignment unit 290A can perform alignment based on the three-dimensional data included in the overlap region extracted by the extraction unit 290B. In a case where the alignment is performed by using the texture information of the workpiece W, a texture feature is estimated based on the luminance or color information constituting the texture information, or the local contrast or the differential value. This texture feature can be used in combination with a shape feature by various operations such as addition and multiplication.

In the present embodiment, the evaluation index of the arrangement posture is calculated such that the amount of overlap region is large and the amount of additional data is large at the time of the next scan such that the alignment of the three-dimensional data by the alignment unit 290A is likely to succeed. Then, the final arrangement posture is determined while the user adjusts the arrangement posture while presenting the arrangement posture of the high evaluation index to the user, and the arrangement posture is superimposed and displayed on the live image such that the user can arrange the actual workpiece W in a posture close to the arrangement posture. Therefore, the alignment with the arrangement posture is performed as an initial position, and thus, a success rate of the alignment can be increased without an additional burden on the user.

The alignment unit 290A can acquire the normal of the three-dimensional data of the workpiece W arranged in the second arrangement posture. The alignment unit 290A can also perform alignment based on an orientation of the normal of the three-dimensional data of the workpiece W arranged in the second arrangement posture, the relative positional relationship calculated by the arithmetic unit 294, an orientation of the normal of the three-dimensional data of the workpiece arranged in the first arrangement posture, and the shape features extracted from the first three-dimensional data and the second three-dimensional data. That is, the alignment unit 290A first narrows down candidates corresponding points based on an angle between an orientation of a normal obtained by rotating the normal of the three-dimensional data of the workpiece W arranged in the first arrangement posture based on the relative positional relationship and the orientation of the normal of the three-dimensional data of the workpiece arranged in the second arrangement posture. Then, based on the narrowed corresponding point candidates, alignment can be performed by using the shape features extracted from the first three-dimensional data and the second three-dimensional data.

In addition, when the user arranges the workpiece W, it is also possible to obtain a high-accuracy initial estimation value by pattern matching between the workpiece of the computer graphics and the actual workpiece W. This is because a relative position between the measurement unit 100 and the workpiece W can be obtained by epipolar geometry from a correspondence relationship between the workpiece of the computer graphics and the actual workpiece W in the live image.

The initial estimation value can be used for detection and extraction of a region where two point clouds overlap, erroneous correspondence detection of a corresponding point candidate, and detection of an erroneous candidate from a position posture candidate obtained from the corresponding point candidate. In a case where an alignment source point cloud P in the already scanned first three-dimensional data and a newly scanned alignment destination point cloud Q are aligned, the alignment unit 290A can specify corresponding points of points included in the first three-dimensional data from the second three-dimensional data and adjust the position posture of the first three-dimensional data and the second three-dimensional data based on the specified corresponding points.

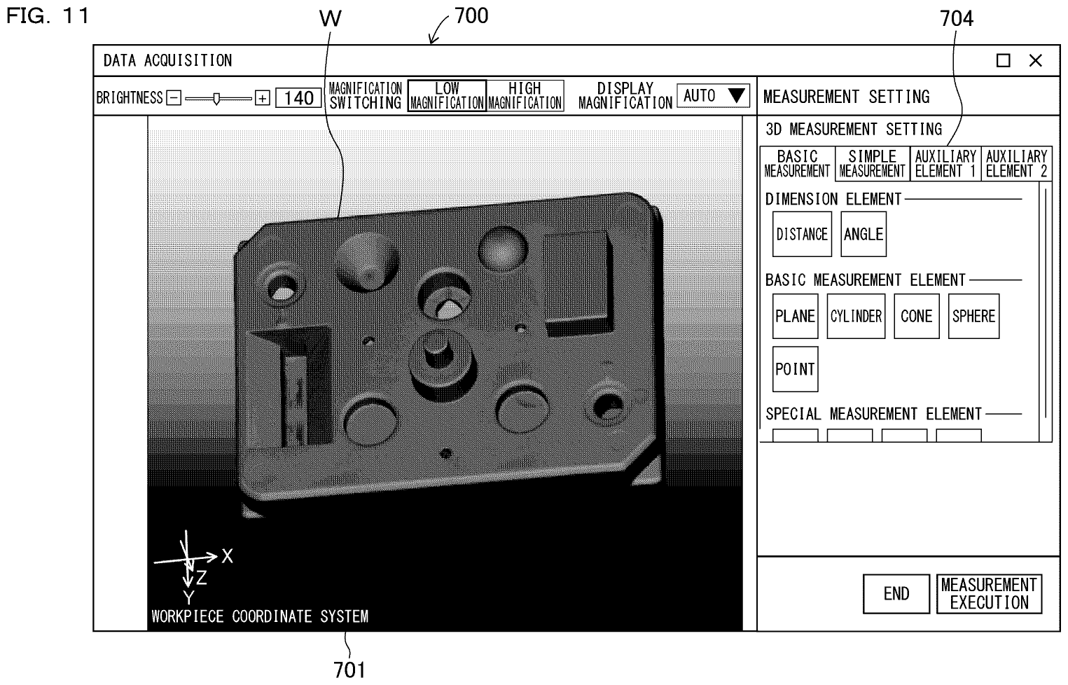

In step SB1 of the flowchart illustrated in FIG. 11, the arithmetic unit 294 acquires the alignment source point cloud P, and in step SB2, the arithmetic unit 294 acquires the alignment destination point cloud Q. In step SB3, the arithmetic unit 294 acquires an initial estimated posture. In step SB4, the alignment source is converted by the arithmetic unit 294 by using the arrangement posture determined as described above. This conversion can be performed by multiplying rotation matrices and adding translation components. As a result, a point cloud P′ after conversion is present at substantially the same position as the point cloud of the alignment destination (step SB5).

In step SB6, the extraction unit 290B can extract Qo by extracting a point cloud P′o in which a point of the point cloud Q is present in the vicinity thereof after conversion and inversely applying the point cloud P′o. These point clouds are referred to as overlap region point clouds. Note that, in a case where the normal vector or the color information is assigned to the point cloud, the accuracy of the overlap region can be changed by using, as a condition of the overlap region extraction, whether or not a point cloud having a high degree of similarity therebetween is present in the vicinity thereof. In addition, the definition of “vicinity” varies depending on how close the user can arrange the actual workpiece W to the workpiece of the computer graphics in the position posture. In addition, the range of “vicinity” may be determined from the scan range of the measurement unit 100 or the size of the workpiece W, and the range of “vicinity” may be changeable by the user.

The alignment unit 290A uses only the overlap region extracted by the extraction unit 290B for alignment. Thus, it is possible to eliminate occurrence of erroneous correspondence of points present in a non-overlap region.

However, the extraction of the overlap region by the extraction unit 290B requires a calculation cost. This is because, for example, when the point cloud P′o is extracted, a point Q positioned closest to each point of the point cloud P′ is searched for, and assuming that the number of points P is M and the number of points Q is N, a calculation cost O is O(M*N).

Thus, it is possible to suppress the occurrence of erroneous correspondence by hidden surface removal as a substitute for the overlap region. This is because the initial estimation value described above is a value with which an overlap region suitable for alignment is obtained by shape analysis. Each of the point clouds of P′ and Q is projected by a virtual camera based on the initial estimation value, and hidden surface removal (only a point at which a depth position viewed from the camera is the minimum is extracted) based on a depth buffer generally used in computer graphics can eliminate the data of the back surface that is erroneous correspondence.

In addition, simple hidden surface removal using the normal vector can be performed as a simpler method. The hidden surface removal can be performed by extracting only points directed in a direction facing the measurement unit 100 from each of the point clouds P′ and Q in a camera coordinate system. Among normal vectors [nx, ny, nz] in the camera coordinate system, only normal vectors of which nz is a negative value are extracted. Thus, the calculation cost can be reduced.

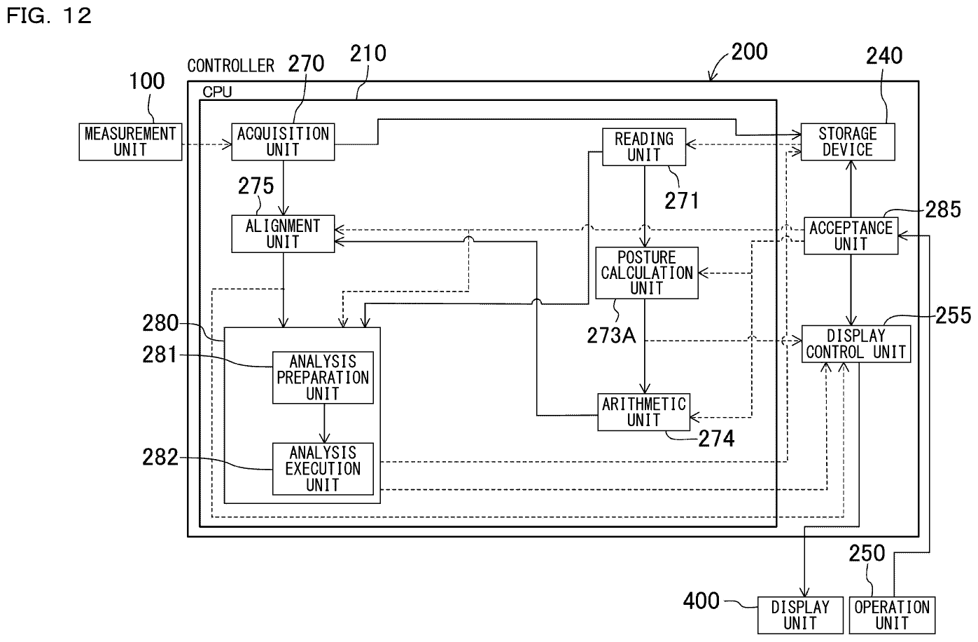

FIG. 12 is a schematic view related to the hidden surface removal. A white arrow W1 extending in a direction orthogonal to each surface of the workpiece W arranged on the mounting surface 142 indicates a normal vector of each surface. In addition, a thin arrow W2 indicates a component of the normal vector parallel to a Z axis of the light reception unit 120, and an arrow W3 indicates a component of the normal vector perpendicular to the Z axis of the light reception unit 120. In the arrow W1, a broken line indicates a normal in which the Z-axis component of the light reception unit 120 is determined to be positive, and a surface corresponding to the broken-line arrow W1 is determined to be a hidden surface.

In step SB8 illustrated in FIG. 11, the extraction unit 290B extracts a shape feature and a luminance feature of each point from the first three-dimensional data corresponding to the first arrangement posture and the second three-dimensional data corresponding to the second arrangement posture acquired by the data acquisition unit 291.

In step SB10, the feature amount acquired in step SB9 is input to the extraction unit 290B to detect the corresponding point. In a case where there is no initial estimation value, a candidate for the corresponding point is obtained by a difference in features between the first three-dimensional data and the second three-dimensional data, a correlation between the first three-dimensional data and the second three-dimensional data, or the like. At this time, a point that is originally present far but has similar features in shape and luminance may be selected as the corresponding point. On the other hand, the initial estimation value is present, and thus, only points in the vicinity and points of which orientations of normal vectors are close can be correspondence candidates, and a correlation value of the feature can be weighted based on a distance between the points and an inner product of the normal vectors.

Assuming that an i-th point of the point cloud P of the alignment source is pi, a point obtained by converting the point pi by the initial estimation value is p′i, a j-th point of the point cloud Q of the alignment destination is qj, a feature vector thereof is F(*), and a normal vector thereof is N(*), an evaluation value can be obtained as w_d(dist(p′i, qj))*wn(1−dot(N(p′i), N(qj)))*CORR(F(p′i), FU(qj)). wd is a weight related to the distance, and wn is a weight related to the orientation of the normal. When this weight is a step function of [1, 0], only a close weight is selected, and when this weight is a monotonically decreasing function, a continuous weight can be applied. Points having high evaluation values are set as corresponding points, and thus, it is possible to eliminate erroneous corresponding points having similar shapes and luminance distributions. A matrix C(pi, qj) representing a corresponding point candidate is obtained as an output of a corresponding point detection unit. It can be expressed by a matrix in which points determined to correspond are 1 and others are 0.

In step SB11, posture candidates are acquired from these corresponding point candidates. A method for obtaining the final arrangement posture of the workpiece W in steps SB12 to SB17 will be described. For example, a RANSAC method can be used as the method for obtaining the final arrangement posture of the workpiece W. Hereinafter, an example using RANSAC will be described. In the posture candidate calculation in RANSAC, a candidate is calculated from a plurality of randomly extracted corresponding points (step SB12). As a result, posture candidates can be acquired (step SB13). In a case where only the coordinates of the points are used, a correspondence relationship between three points is required, and in a case where the normal line and the coordinates of the points are used, a correspondence relationship between two points is required. Taking the correspondence relationship between three points as an example, a rotation matrix R and a translation vector t in which a square distance between corresponding p′ and q is the smallest are obtained by linear and nonlinear optimization (step SB14).

$$Sum\_C ( p\_i , q\_j ) {( q\_j - {p}^{′} \_i * R + t )}^{∧} 2$$

The present embodiment is not limited to this candidate calculation method, and a candidate can be calculated by using any method. For example, a method using graph cutting is also applicable to the present embodiment.

Whether or not the rotation matrix and translation vector obtained in this manner are close to the initial estimation value is determined to detect whether or not correct candidates are obtained. When a sum of squares of each element is used, an initial estimation value is t, and a candidate is t′, the translation vector can be defined as dist(t, t′)=(t_x−t′_x)\hat{ }2+(t_y−t′_y)\hat{ }2+(t_z−t′_z)\hat{ }2. In addition, the rotation matrix can be obtained as Dist(R, R′)=arccos[(trace(R\hat{ }T*R′)−1)/2].

An arrangement posture in which an error of the translation component is within a predetermined dimension and an angular error is within a predetermined angle can be extracted as a correct candidate. In step SB16, a detected posture is obtained from these candidates by final posture selection processing, and a post-selection candidate is acquired (step SB17). This is obtained by a method for evaluating by a predetermined evaluation value. For example, conversion is performed as P″=R*P′+t by using the rotation matrix R representing the candidate posture and the translation component t, and the number of points where the points of the point cloud Q satisfying dist(P″−Q)<threshold are present can be set as the evaluation value. However, the calculation of the evaluation value to be combined with in the present embodiment is not particularly limited. Since this evaluation value calculation can also be performed only in the overlap region, it is possible to suppress a phenomenon in which the evaluation value erroneously increases due to the presence of the corresponding points in the vicinity thereof although the points do not overlap. The second arrangement posture is specified in this manner, and the workpiece W arranged in the specified second arrangement posture is scanned by the measurement unit 100. Thus, it is possible to acquire the second three-dimensional data having high accuracy of alignment with the first three-dimensional data and a large amount of additional data.

When the alignment between the first three-dimensional data and the second three-dimensional data is performed, the alignment unit 290A can perform alignment based on the shape feature and the image feature of the three-dimensional data. That is, the analysis module 290 includes a shape feature extraction unit (first extraction unit) 290C that extracts the shape features of the first three-dimensional data and the second three-dimensional data acquired by the data acquisition unit 291, and an image feature extraction unit (second extraction unit) 290D. The shape feature extraction unit 290C includes a neural network including an input layer, a plurality of intermediate layers, and an output layer. The input layer of the neural network is a portion that accepts inputs of the first three-dimensional data and the second three-dimensional data acquired by the data acquisition unit 291. The plurality of intermediate layers of the neural network are portions that extract the shape features based on the inputs accepted by the input layer. The output layer of the neural network is a portion that outputs the shape features extracted in the intermediate layers. On the other hand, the image feature extraction unit 290D is a portion that extracts an image feature from the texture information included in each of the first three-dimensional data and the second three-dimensional data acquired by the data acquisition unit 291.

As described above, in the present embodiment, when the alignment between the first three-dimensional data and the second three-dimensional data is performed, deep learning is used to incorporate image features such as brightness and color into the feature vector. In a case where the feature vector of each point of the image or the point cloud is calculated, it is possible to perform a “convolution” arithmetic operation of multiplying coordinates and colors which are information of the own point and information of peripheral points by coefficients and obtaining a sum or a maximum value thereof. For example, in a convolutional neural network (CNN) in an image, a large number of 3×3 filters having coefficients determined by learning in advance are provided, an output value of each filter is arranged, and the arranged output vector is set as an output vector of the point, and a result obtained by repeating the output vector many times with different filters is set as a feature vector.

In the case of the point cloud included in the first three-dimensional data or the second three-dimensional data, since there is no guarantee that data is present at a regular interval unlike the image, other methods can be used. For example, a method for three-dimensionally applying a CNN by sampling a point in a voxel, multiplying the point by a coefficient when the point is present and outputting 0 when the point is not present, PointNet++ for applying the same coefficient to each point to obtain a maximum value of the output, and a method such as KPConv for performing interpolation arithmetic operation on a deviation from the position of the point cloud with respect to a coefficient determined on a grid to obtain the coefficient and convoluting the coefficient can be exemplified.

In the processing of the point cloud included in the first three-dimensional data or the second three-dimensional data, since how the points are arranged is unknown, a calculation amount becomes enormous and a processing time becomes long. In the technical field of the three-dimensional scanner 1 as in this example, when the processing time becomes long, since a work is delayed and does not proceed, it is necessary to set the processing time without a problem in practical use. Therefore, the number of points that can be processed is naturally limited, and as an example, an upper limit of the number of key points may be set to several thousand points, and about several tens of thousands of points in the entire point cloud. Since the number of point clouds that can be scanned by the measurement unit 100 at a time is several million points, points used in deep learning need to be thinned down to about 1% thereof.

In a case where image information is most simply input to the input layer of the neural network, the image information (luminance and color) may be input in addition to the coordinates and normal vector, but in this case, the number of pieces of data input to the input layer is too small, and information useful as an image is lost. Thus, there is a case where performance is not improved.

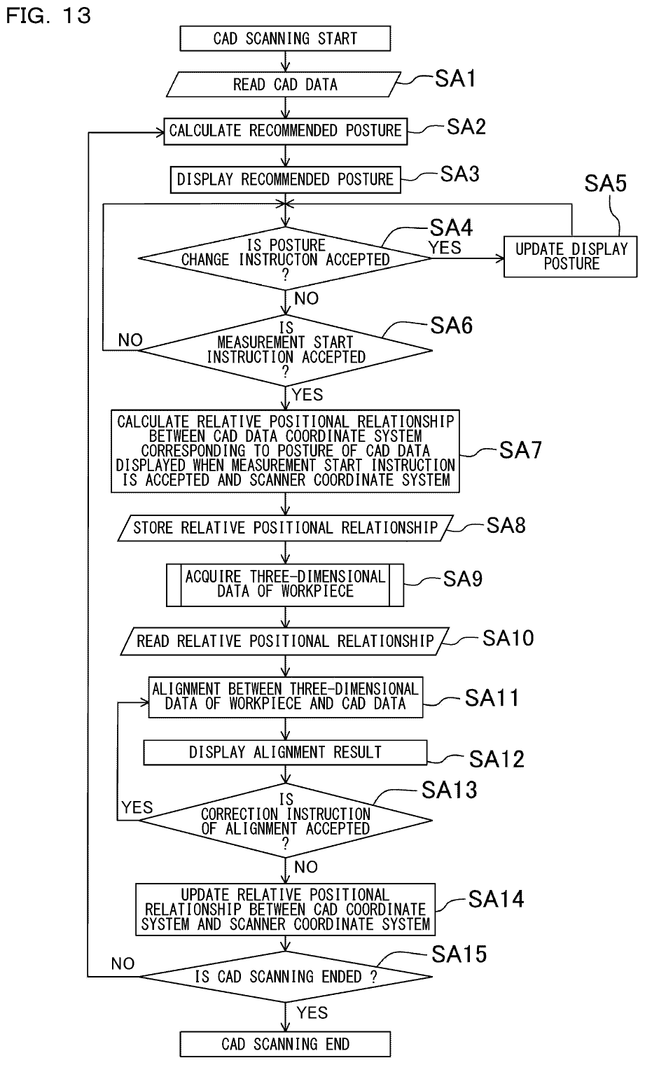

Hereinafter, processing of extracting the shape features and the image features will be described with reference to the flowchart illustrated in FIG. 13. In step SC1, the analysis module 290 acquires a point cloud (input point cloud) of the first three-dimensional data or the second three-dimensional data. In steps SC2 and SC3, coarse thinning processing and dense thinning processing are performed, respectively. That is, as illustrated in FIG. 5, the analysis module 290 includes a resolution conversion unit 290E that converts a resolution of the first three-dimensional data and a resolution of the second three-dimensional data acquired by the data acquisition unit 291. The resolution conversion unit 290E executes first conversion processing (coarse thinning processing) of converting the first three-dimensional data and the second three-dimensional data into three-dimensional data having a first resolution lower than the resolutions acquired by the data acquisition unit 291. That is, the resolution conversion unit 290E converts the first three-dimensional data acquired by the data acquisition unit 291 into third three-dimensional data that is three-dimensional data having the first resolution, and converts the second three-dimensional data acquired by the data acquisition unit 291 into fourth three-dimensional data that is three-dimensional data having the first resolution. In the first conversion processing by the resolution conversion unit 290E, since the resolution of the three-dimensional data acquired by the data acquisition unit 291 is reduced to become low-resolution three-dimensional data, the number of points of the three-dimensional data is smaller than the number of points at the time of acquisition by the data acquisition unit 291.

The first conversion processing by the resolution conversion unit 290E corresponds to step SC2. Third three-dimensional data (third point cloud) and fourth three-dimensional data (fourth point cloud), which are the shape feature extraction point clouds (Q), are generated through step SC2, and the shape feature extraction unit 290C acquires the shape feature extraction point clouds (Q) in step SC4. The shape feature extraction unit 290C extracts the shape feature from the shape information included in each of the first three-dimensional data having the first resolution and the second three-dimensional data having the first resolution converted by the resolution conversion unit 290E.

The resolution conversion unit 290E executes second conversion processing (dense thinning processing) of converting the first three-dimensional data and the second three-dimensional data acquired by the data acquisition unit 291 into three-dimensional data having a second resolution lower than the resolutions acquired by the data acquisition unit 291 and higher than the first resolution. That is, the resolution conversion unit 290E converts the first three-dimensional data acquired by the data acquisition unit 291 into fifth three-dimensional data that is three-dimensional data having the second resolution, and converts the second three-dimensional data acquired by the data acquisition unit 291 into sixth three-dimensional data that is three-dimensional data having the second resolution. In the second conversion processing by the resolution conversion unit 290E, since the resolution of the three-dimensional data acquired by the data acquisition unit 291 is reduced to become low-resolution three-dimensional data, the number of points of the three-dimensional data is smaller than the number of points at the time of acquisition by the data acquisition unit 291, but since the resolution is higher than that of the first conversion processing, the number of points is larger than that of the first conversion processing. The second conversion processing by the resolution conversion unit 290E corresponds to step SC3.

The fifth three-dimensional data (fifth point cloud) and the sixth three-dimensional data (sixth point cloud) (Q′), which are the image feature extraction point clouds, are generated through step SC3, and the image feature extraction unit 290D acquires the image feature extraction point clouds (Q′) in step SC5. The image feature extraction unit 290D extracts the image feature from the texture information included in each of the first three-dimensional data and the second three-dimensional data having the second resolution converted by the resolution conversion unit 290E.

Note that, step SC3 described above may be skipped, and the image feature extraction unit 290D may generate the image feature extraction point clouds by using the first three-dimensional data and the second three-dimensional data acquired by the data acquisition unit 291.

In the first conversion processing and the second conversion processing, for example, random thinning for randomly selecting a predetermined number of pieces of data, voxel thinning for calculating a voxel grid and reducing a plurality of point clouds entering a voxel to only one average value thereof, or the like can be used. Here, a point cloud before thinning (point cloud before second conversion processing) may be used as the point cloud for image feature extraction.

In step SC6, the shape feature extraction unit 290C extracts key points from the low-resolution first three-dimensional data and second three-dimensional data. When the key points are extracted, for example, there are a method for randomly selecting and extracting the key points, a method for extracting characteristic points as the key points by deep learning or rule-based point cloud analysis, and the like, and any method may be used. The key points extracted by the shape feature extraction unit 290C are acquired by the shape feature extraction unit 290C (step SC7).

In step SC8, the analysis module 290 acquires the shape feature extraction point cloud (Q) acquired in step SC4 and the key points acquired in step SC7, and the analysis module 290 samples points around the key points. At this time, the points for shape feature extraction are sampled based on the shape feature extraction point cloud (Q) acquired in step SC4.

In step SC12 proceeding through step SC5, the analysis module 290 acquires the image feature extraction point cloud (Q′) acquired in step SC5 and the key points acquired in step SC7, and the analysis module 290 samples points around the key points. The points for image feature calculation are sampled based on the image feature extraction point cloud (Q′) acquired in step SC5. In addition, since the number of points of the image feature extraction point cloud (Q′) is large, a vicinity range to be sampled may be narrowed as compared with the shape feature extraction point cloud (Q).

In step SC9 proceeding through step SC8, the shape feature is input to the shape feature extraction unit 290C. For example, a shape feature vector can be calculated only from the vicinity of a point sampled for a shape feature. A method for calculating the shape feature vector is not particularly limited, but for example, a method for projecting image information of a point cloud according to a normal of a key point to obtain a patch image and calculating a feature vector by calculation such as CNN or scale-invariant feature transform (SIFT), a method for creating a histogram based on RGB or luminance information of a sampled point and using the histogram as a feature vector, or the like can be used. In step SC10, the shape feature extraction unit 290C calculates shape feature vectors of the key points.

On the other hand, in step SC13 proceeding through step SC12, the image feature is input to the image feature extraction unit 290D. Here, the feature vector of the image is calculated. The feature vectors for the key points are calculated by using all the points around the key points sampled from the image feature extraction point cloud (Q′). In step SC14, the image feature extraction unit 290D calculates image feature vectors of the key points, and in step SC15, the image feature vectors calculated by the image feature extraction unit 290D are acquired.

That is, the image feature extraction unit 290D extracts key points to be used for calculation of the shape features from the low-resolution first three-dimensional data and second three-dimensional data. The image feature extraction unit 290D can specify regions corresponding to the extracted key points from the first three-dimensional data and the second three-dimensional data before being converted by the resolution conversion unit 290E. The image feature extraction unit 290D extracts image features from the specified corresponding regions.

Note that, when the feature vector of the image is calculated, the image feature extraction unit 290D may specify the regions corresponding to the key points extracted by the shape feature extraction unit 290C from the first three-dimensional data and the second three-dimensional data, and extract the image features from the regions corresponding to the key points specified by the image feature extraction unit 290D.

In the calculation of the shape feature vectors in step SC11, 3-dimensional to 6-dimensional vectors having X, Y, and Z coordinates and pieces of normal information Nx, Ny, and Nz as necessary may be input. As described above, the shape feature extraction unit 290C extracts key points as partial regions to be used for calculation of the shape features from the low-resolution first three-dimensional data and second three-dimensional data, and extracts the shape features for the extracted key points.

In step SC16, a pair candidate is obtained by comparing the shape feature vector, the image feature vector, or the shape feature vector including the image feature with the key points of the three-dimensional data of the alignment source and the three-dimensional data of the alignment destination. A method for calculating the pair candidate is not particularly limited, and examples thereof include a method for obtaining a distance of the feature vector and forming a pair with a small distance, and a method for forming a pair with a high output value of a deep learning module that outputs a degree of correspondence. A mean square (L2 distance) or a degree of cosine similarity is used as the distance. In addition, at this time, for comparison between the shape feature vector and the image feature vector, a method for simply obtaining a pair by using a vector obtained by combining both vectors as an input, a sum of distances calculated by the shape feature vector and the image feature vector, a maximum value, a minimum value, and the like can be used. Due to the use of a point of the pair candidate, a positional relationship (rotation and translation) between the point clouds can be obtained by RANSAC or a deep learning based method.

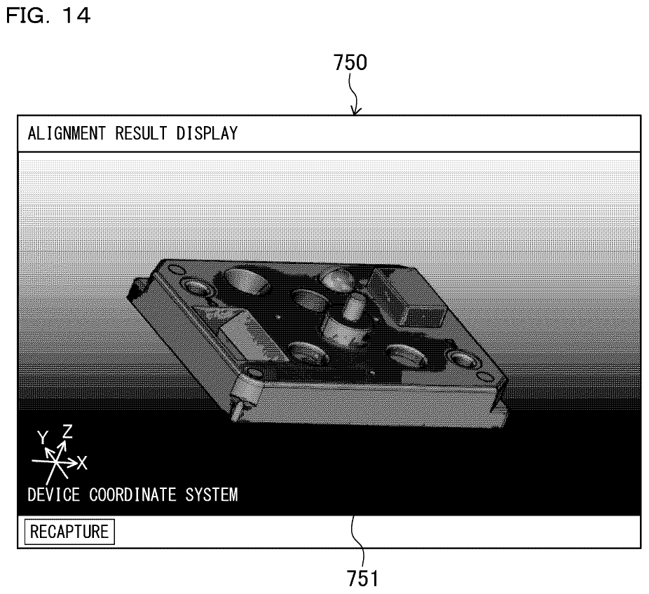

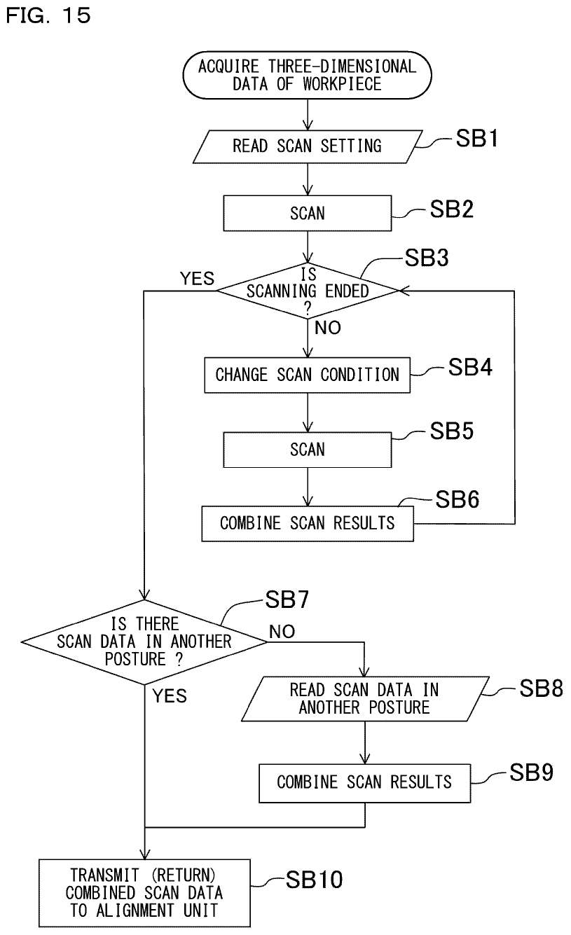

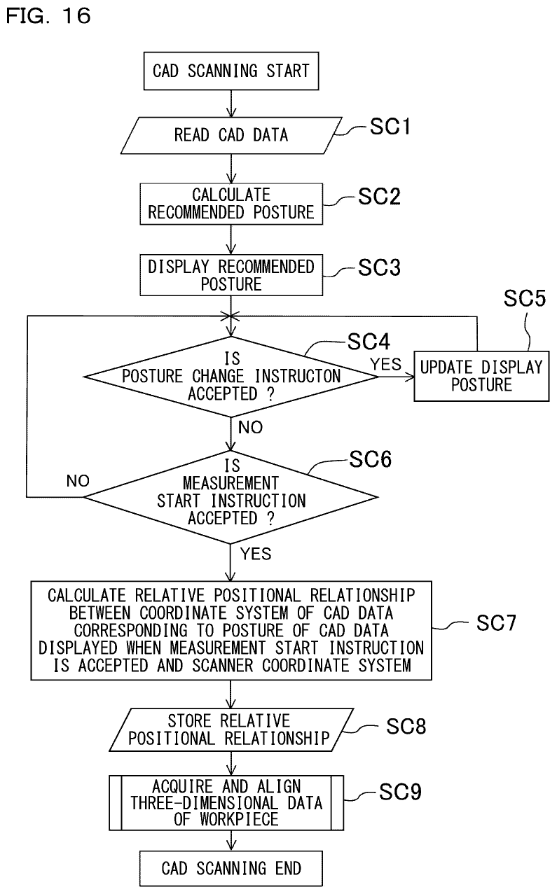

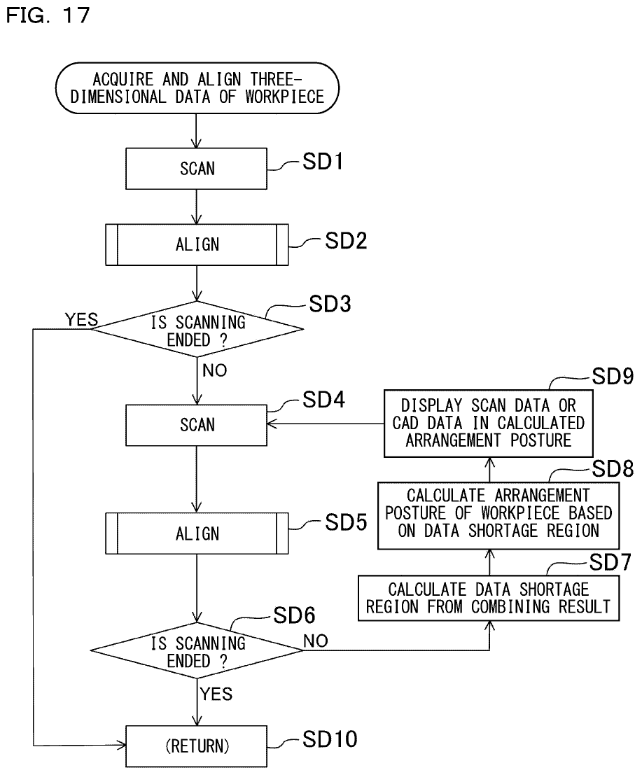

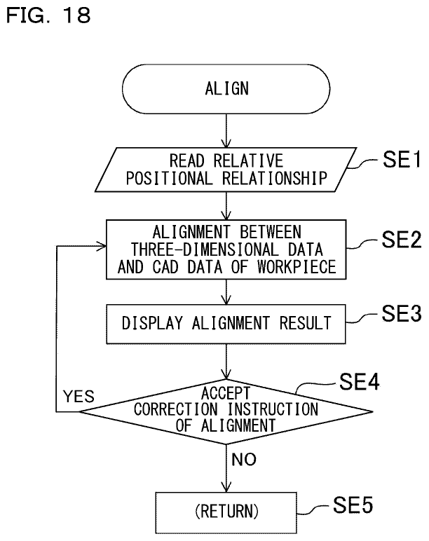

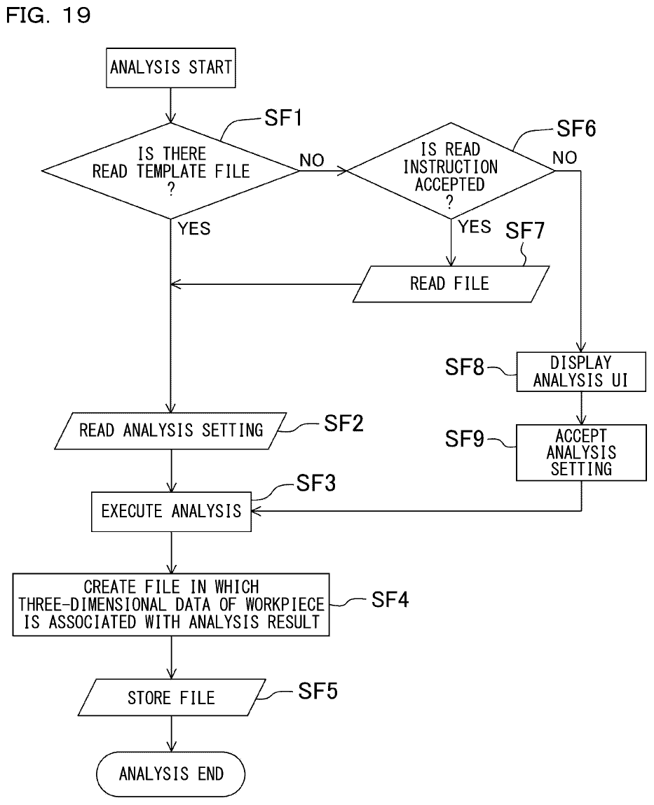

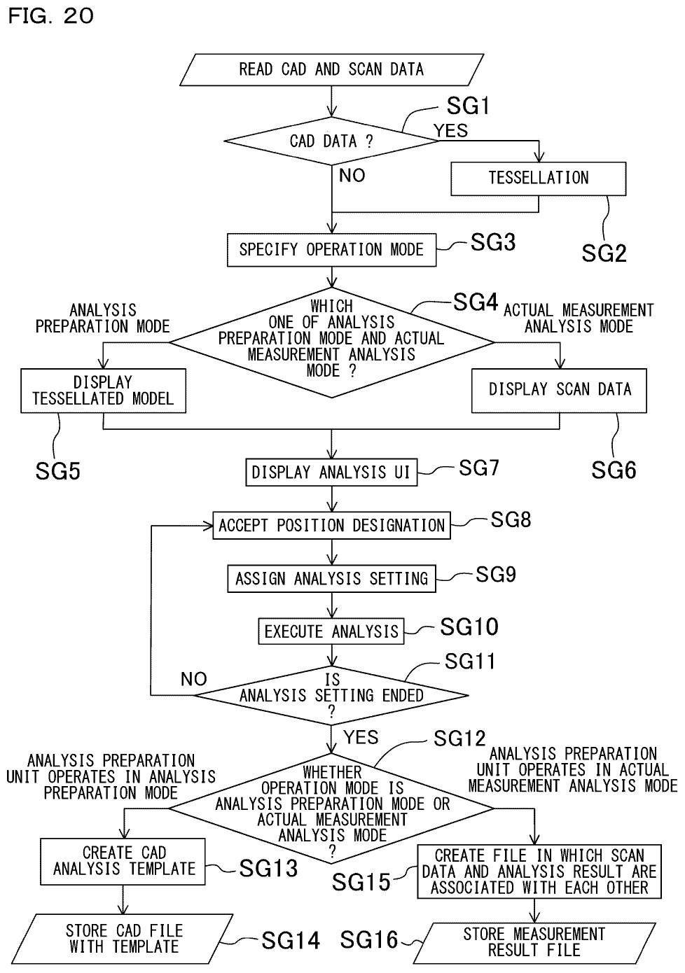

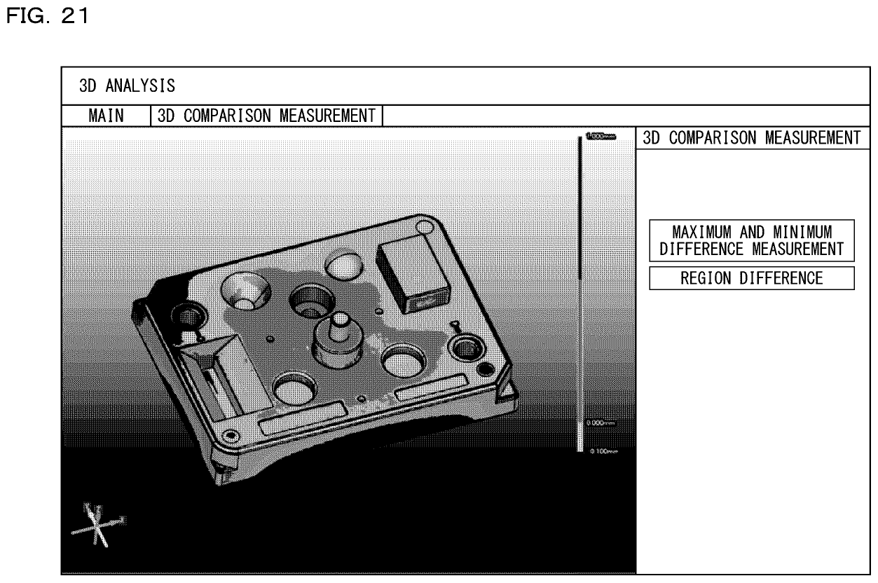

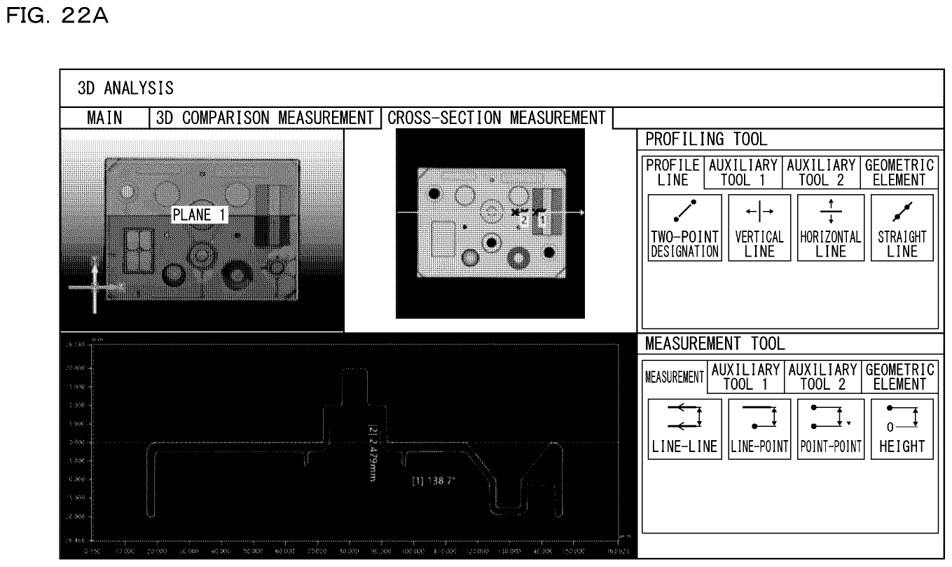

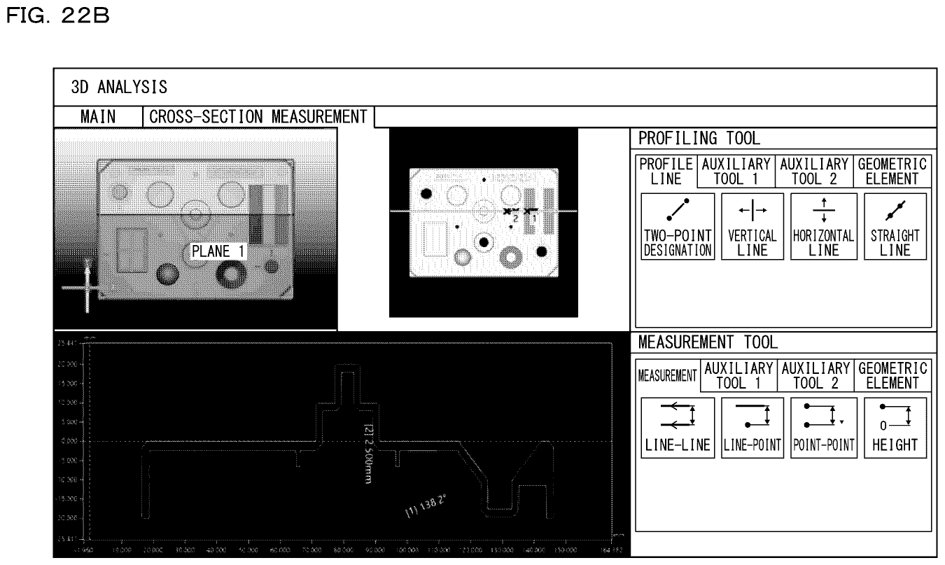

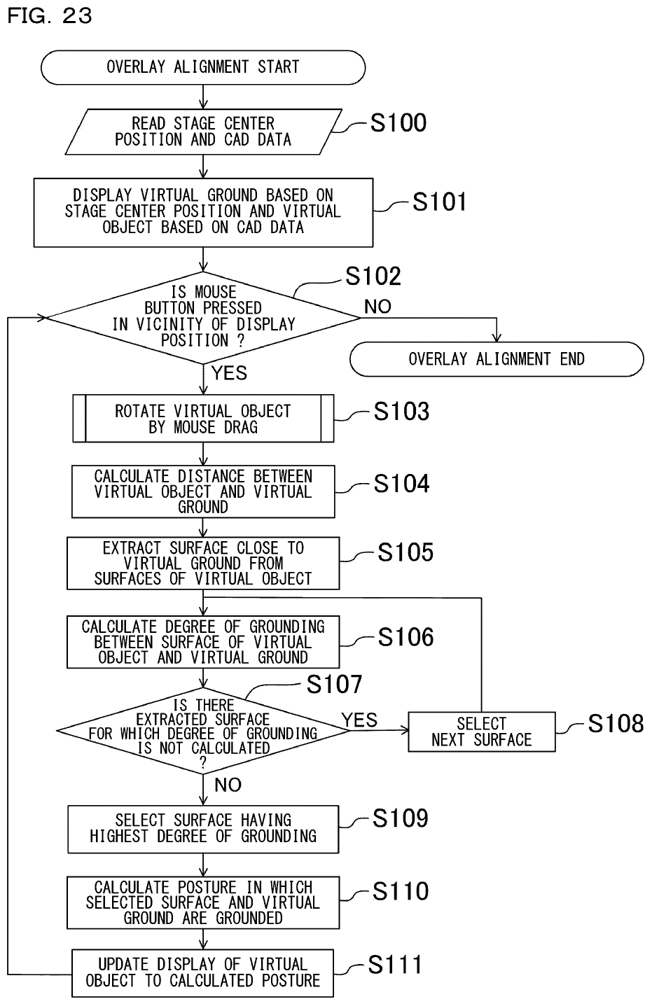

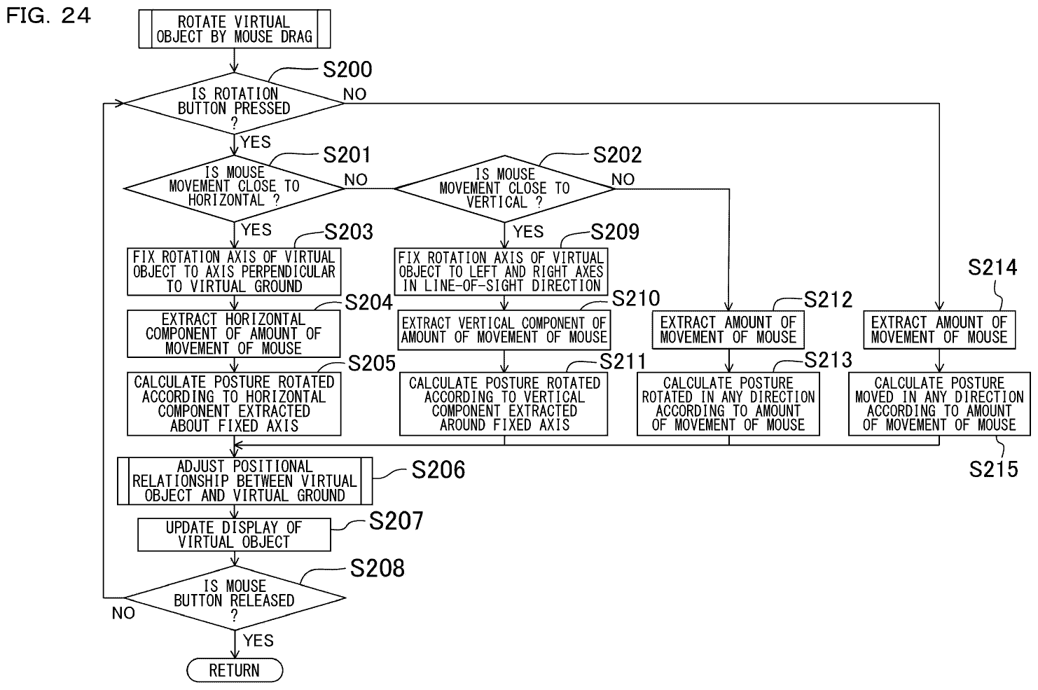

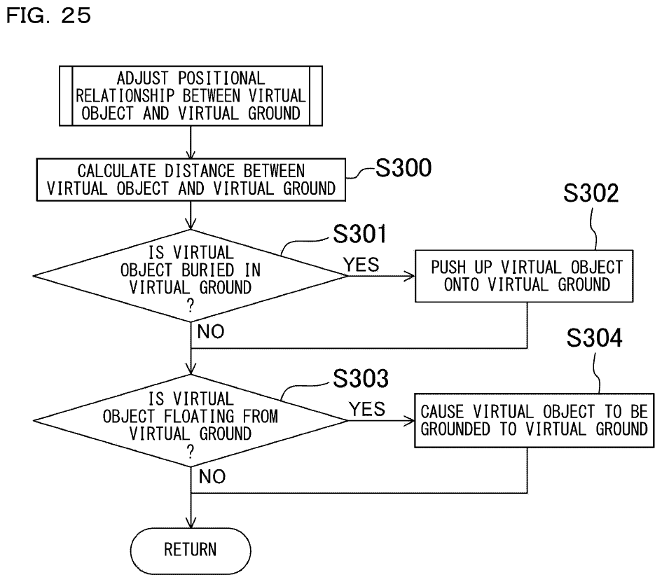

FIG. 14 illustrates a case where the vector to which the image feature is added is input to the shape feature extraction unit in the case of the processing of extracting the shape feature and the image feature. The processing proceeds to step SC9′ in FIG. 14 through step SC8 in FIG. 13, and the processing proceeds to step SC13′ in FIG. 14 through step SC12 in FIG. 13. Steps SC13′ to SC15′ are the same as steps SC13 to SC15 in FIG. 13. In step SC10′, the image feature vector is input to the shape feature extraction unit 290C. In this case, the output shape feature vector is a shape feature vector already including the image feature (step SC11′). Step SC16′ is the same as step SC16 in FIG. 13.

The alignment unit 290A executes processing of combining global alignment and local alignment as processing of aligning the point cloud of the first three-dimensional data and the point cloud of the second three-dimensional data with high accuracy. In this processing, the global alignment is performed by a low-resolution point cloud, and the local alignment converted by using the position thereof is performed by a high-resolution point cloud. For example, the local alignment is performed by using point cloud data having the first resolution (low resolution) for the shape feature extraction in the global alignment, using a point cloud having the third resolution higher than the first resolution for the image feature extraction, and using, as an input, point cloud data having the second resolution higher than both the first resolution and the third resolution. Note that, the point cloud data used for the local alignment may be the point cloud data having the second resolution, or may be the point cloud data having the same resolution as the resolution of the point cloud generated by receiving the light reception signal in the point cloud acquisition unit 263a.

Specifically, the alignment unit 290A acquires the shape feature extracted by the shape feature extraction unit 290C and the image feature extracted by the image feature extraction unit 290D. In this case, the alignment unit 290A can execute the global alignment based on the shape features extracted by the shape feature extraction unit 290C and the image features extracted by the image feature extraction unit 290D. In this case, the alignment unit 290A executes first alignment processing of calculating a low-accuracy alignment parameter indicating a relative position posture of the second three-dimensional data with respect to the first three-dimensional data.

When the low-accuracy alignment parameter is calculated, steps SD1 to SD7 are performed as illustrated in FIG. 15. Steps SD1 to SD5 are the same as steps SC1 to SC5 illustrated in FIG. 13. In step SD6 illustrated in FIG. 15, the shape feature extraction point cloud acquired in step SD4 and the image feature extraction point cloud acquired in step SD5 are input to the alignment unit 290A. The alignment unit 290A executes the global alignment of the input point cloud and calculates the low-accuracy alignment parameter.

After the first alignment processing, the alignment unit 290A acquires the low-accuracy alignment parameter calculated by the first alignment processing, the first three-dimensional data, and the second three-dimensional data. The alignment unit 290A can execute the local alignment based on the low-accuracy alignment parameter, the first three-dimensional data, and the second three-dimensional data. In this case, the alignment unit 290A executes second alignment processing of calculating a high-accuracy alignment parameter indicating a relative position posture of the second three-dimensional data with respect to the first three-dimensional data.

When the high-accuracy alignment parameter is calculated, as illustrated in FIG. 16, in step SE1, the analysis module 290 acquires the input point cloud of the first three-dimensional data. In step SE2, the analysis module 290 acquires the input point cloud of the second three-dimensional data. In step SE3, the analysis module 290 acquires the low-accuracy alignment parameter calculated by the processing of the flowchart illustrated in FIG. 15.

The analysis module 290 includes a coordinate conversion unit 290F that performs coordinate conversion of the first three-dimensional data based on the low-accuracy alignment parameter calculated by the processing of the flowchart illustrated in FIG. 15. In step SE4, the coordinate conversion unit 290F performs coordinate conversion of the input point cloud of the first three-dimensional data based on the low-accuracy alignment parameter. In step SE5, the point cloud after coordinate conversion is acquired.

In step SE6, the input point cloud of the second three-dimensional data acquired in step SE2 and the point cloud after coordinate conversion acquired in step SE4 are input to the alignment unit 290A. The alignment unit 290A executes the local alignment of the input point cloud and calculates the high-accuracy alignment parameter. In step SE7, the high-accuracy alignment parameter is acquired. As described above, in the second alignment processing, the alignment unit 290A acquires the first three-dimensional data and the second three-dimensional data on which the coordinate conversion is performed by the coordinate conversion unit 290F, and executes the local alignment based on the first three-dimensional data and the second three-dimensional data.

After the alignment processing in step SA14 illustrated in FIG. 6 is executed as described above, combining processing is executed. That is, as illustrated in FIG. 5, the analysis module 290 includes a combining unit 290G. The combining unit 290G is a portion that combines the first three-dimensional data of the workpiece W arranged in the first arrangement posture aligned by the alignment unit 290A and the second three-dimensional data of the workpiece W arranged in the second arrangement posture to generate combined three-dimensional data. The combining unit 290G can also acquire the first mesh data as the first three-dimensional data and the second mesh data as the second three-dimensional data. In this case, the combining unit 290G combines the first mesh data and the second mesh data to generate combined mesh data as the combined three-dimensional data.

In addition, the removal of the hidden surface illustrated in FIG. 12 is performed before the combined three-dimensional data is generated, and is used for alignment by the alignment unit 290A. That is, the alignment unit 290A can perform alignment by using the three-dimensional data from which the hidden surface is removed. Then, the combining unit 290G generates the combined three-dimensional data based on the alignment performed by using the three-dimensional data from which the hidden surface is removed. Here, the generation of the combined three-dimensional data is performed before hidden surface removal, that is, using the three-dimensional data including the hidden surface.

The combining unit 290G can acquire the shape information of the workpiece W based on the first light reception signal output from the light reception unit 120, and can acquire the texture information of the workpiece W based on the second light reception signal output from the light reception unit 120. In a case where the shape information of the workpiece W and the texture information of the workpiece W are acquired, the combining unit 290G generates the three-dimensional data including the shape information and the texture information of the workpiece W.

In addition, in a case where the data acquisition unit 291 acquires the combined three-dimensional data obtained by combining the first three-dimensional data and the second three-dimensional data, the posture calculation unit 293 can calculate the arrangement posture different from the first arrangement posture based on the combined three-dimensional data acquired by the data acquisition unit 291. As described above, the arrangement posture at the time of scanning performed in addition to the already generated combined three-dimensional data can be presented to the user. In this case, the additional data amount estimation unit 296 estimates the amount of additional data to be added to the combined three-dimensional data. In addition, the overlap region estimation unit 295 estimates the overlap region for the combined three-dimensional data. As a result, it is possible to present the evaluation index based on the amount of additional data and the amount of overlap region when scanning is performed in an additional arrangement posture to the user.

When the combining processing is completed, the processing proceeds to step SA15 illustrated in FIG. 6. In step SA15, the user determines whether or not a part requiring scanning is present in the workpiece W. When the part requiring scanning is present on the workpiece W, the processing proceeds to step SA2, and the workpiece W is arranged on the mounting surface 142 in the third arrangement posture and scanned by the measurement unit 100. By repeating this, all necessary scan parts can be scanned. In a case where NO is determined in step SA15, a full-surface scan model is acquired in step SA16. Note that, the full-surface scan model is not essential, and any model may be used as long as the user can scan a necessary part.

Next, an example of scan processing in a case where there is a reference model such as CAD data of the workpiece W or measured three-dimensional data will be described with reference to the flowchart of FIG. 17. In step SG1, the reading unit 292 of the analysis module 290 reads a CAD model (reference model) from the storage device 240, and acquires the CAD model in step SG2. In step SG3, evaluation value calculation and posture candidate proposal are performed in a manner similar to step SA4 of FIG. 6. In step SG3, since there is CAD data, the posture calculation unit 293 analyzes the CAD data read by the reading unit 292. The posture calculation unit 293 estimates the amount of acquired data (amount of additional data) by analyzing the CAD data, and calculates the recommended arrangement posture based on the estimated amount of data. In addition, the posture calculation unit 293 analyzes the CAD data read by the reading unit 292, and estimates an overlap region between the three-dimensional data and the CAD data acquired in the case of being arranged in the recommended arrangement posture. The posture calculation unit 293 calculates the recommended arrangement posture based on the estimated overlap region.

In step SG4, for example, the user selects the posture candidate on the user interface screen 700 as illustrated in FIG. 8. In step SG5, the user determines whether or not the candidate posture displayed on the display unit 400 is a desired posture. In a case where the posture is not the desired posture, the processing proceeds to step SG6, and the arrangement posture of the workpiece W is adjusted on the computer graphics. In step SG7, the overlap region estimation unit 295 estimates the amount of overlap region in the arrangement posture for which adjustment is completed, and the additional data amount estimation unit 296 estimates the amount of additional data. The analysis module 290 newly calculates the evaluation index based on the estimated amount of overlap region and the estimated amount of additional data and presents the evaluation index to the user.

In a case where it is determined in step SG5 that the posture is the desired posture, the processing proceeds to step SG8, and the analysis module 290 generates the workpiece (model) of computer graphics in the determined arrangement posture. The display control unit 255 superimposes the workpiece of the computer graphics generated by the analysis module 290 on the live image acquired by the data acquisition unit 291 and displays the superimposed image on the display unit 400.

In step SG9, the user mounts the workpiece W on the mounting surface 142 at a temporary position. Then, the workpiece W is captured together with the mounting surface 142 by the light reception unit 120, and the live image is acquired by the data acquisition unit 291 and displayed on the display unit 400. While viewing the live image on the display unit 400, the user moves or rotates the actual workpiece W until the actual workpiece W overlaps the workpiece of the computer graphics.

In step SG10, the user determines whether or not the actual workpiece W is mounted so as to overlap the workpiece of the computer graphics. In a case where the actual workpiece W cannot be mounted so as to overlap the workpiece of the computer graphics, the processing proceeds to step SG4, and another arrangement posture is selected. In a case where the actual workpiece W is mounted so as to overlap the workpiece of the computer graphics, since the workpiece W is in the first arrangement posture, the processing proceeds to step SG11, and the measurement unit 100 scans the workpiece W arranged in the first arrangement posture. In step SG12, the first three-dimensional data is acquired. In step SG13, the alignment unit 290A performs the alignment between the first three-dimensional data and the CAD data that is the reference model. In step SG14, the analysis module 290 acquires the aligned CAD model.

In step SG15, the evaluation value calculation and the posture candidate proposal are performed. In step SG16, the user selects the posture candidate, and then the processing proceeds to step SG17. In a case where the posture is not the desired posture, after adjustment in step SG18, the evaluation value is updated in step SG19, and then the processing proceeds to step SG17. In a case where the posture is the desired posture, the processing proceeds to step SG20, and the display control unit 255 superimposes the workpiece of the computer graphics generated by the analysis module 290 on the live image acquired by the data acquisition unit 291 and displays the superimposed image on the display unit 400. Here, the workpiece of the computer graphics may be the first three-dimensional data or the reference model acquired in step SG12. In addition, the first three-dimensional data and the reference model may be simultaneously displayed on the display unit 400, or may be switched and displayed.

In step SG21, the user moves or rotates the actual workpiece W until the actual workpiece W overlaps the workpiece of the computer graphics while viewing the live image on the display unit 400.

In step SG22, the user determines whether or not the actual workpiece W is mounted so as to overlap the workpiece of the computer graphics. In a case where the actual workpiece W cannot be mounted so as to overlap the workpiece of the computer graphics, the processing proceeds to step SG16, and another arrangement posture is selected. In a case where the actual workpiece W is mounted so as to overlap the workpiece of the computer graphics, the processing proceeds to step SG23, and the measurement unit 100 scans the workpiece W in the arrangement posture (second arrangement posture). In step SG24, the alignment unit 290A performs alignment with the acquired second three-dimensional data, and in step SG25, a partial scan model is acquired. In step SG26, the alignment unit 290A executes alignment processing of the three-dimensional model, and the combining unit 290G executes the combining processing. In step SG27, the user determines whether or not there is the part requiring scanning. When there is the part requiring scanning, the processing proceeds to step SG12. When there is no scan part, the full-surface scan model is acquired in step SG28. The full-surface scan model acquired in step SG28 may be output together with the CAD model in which the alignment processing is executed by the alignment unit 290A in step SG26. Further, the full-surface scan model and the CAD model may be displayed in a state of being aligned on the display unit 400.

In this embodiment, as schematically illustrated in FIG. 19, the alignment unit 290A performs alignment between first three-dimensional data A and second three-dimensional data B based on a first alignment parameter (first positional relationship) that is a positional relationship between the first three-dimensional data A and the second three-dimensional data B, and the combining unit 290G combines the first three-dimensional data (first mesh data) A and the second three-dimensional data (second mesh data) B acquired by the data acquisition unit 291 to generate combined three-dimensional data AB. Thereafter, when the data acquisition unit 291 acquires third three-dimensional data C, the alignment unit 290A performs alignment between the combined three-dimensional data AB obtained by combining the first three-dimensional data A and the second three-dimensional data B and the third three-dimensional data C based on a second alignment parameter (second positional relationship) that is a positional relationship between the combined three-dimensional data AB and the third three-dimensional data C, and the combining unit 290G combines the combined three-dimensional data AB with the third three-dimensional data (third mesh data) C acquired by the data acquisition unit 291 to generate combined three-dimensional data ABC. At this time, for example, when an editing unit 290H accepts an input for editing the position or shape of at least one piece of mesh data among the first mesh data, the second mesh data, and the third mesh data, the storage device 240 stores the first mesh data, the second mesh data, and the third mesh data. The editing of the shape of the mesh data includes, for example, removal of a part of the point cloud.

In addition, when the data acquisition unit 291 acquires fourth three-dimensional data D, the alignment unit 290A performs alignment between the combined three-dimensional data ABC and the fourth three-dimensional data D based on a third alignment parameter (third positional relationship) that is a positional relationship between the combined three-dimensional data ABC and the fourth three-dimensional data D, and the combining unit 290G combines the combined three-dimensional data ABC and the fourth three-dimensional data (fourth mesh data) D acquired by the data acquisition unit 291 to generate combined three-dimensional data ABCD. When the editing unit 290H accepts an input for editing the position or shape of the fourth mesh data, the storage device 240 stores the fourth mesh data.

As described above, the user can obtain the three-dimensional data of the entire workpiece W by sequentially combining the two pieces of three-dimensional data. The sequential combining is performed, and thus, a processing load of the mesh data conversion from the point cloud becomes constant, and processing of combining the pieces of mesh data on which the thinning processing is performed also becomes constant. For example, the processing load can be reduced as compared with processing of collectively converting all original point clouds constituting the combined three-dimensional data ABCD. Note that, the combined three-dimensional data ABCD is not limited to the method for sequentially adding the fourth three-dimensional data to the combined three-dimensional data ABC, and may be generated by combining the first three-dimensional data, the second three-dimensional data, the third three-dimensional data, and the fourth three-dimensional data based on the positional relationship among the pieces of three-dimensional data.

The display control unit 255 displays the combined three-dimensional data generated by the combining unit 290G on the display unit 400, and displays the first three-dimensional data and the second three-dimensional data in an identifiable manner on the display unit 400. That is, the display control unit 255 generates a user interface screen 800 as illustrated in FIG. 18 and displays the user interface screen on the display unit 400. A first display region 801 in which the first three-dimensional data (first mesh data) is displayed, a second display region 802 in which the second three-dimensional data (second mesh data) is displayed, and a third display region 803 in which the combined three-dimensional data (combined mesh data) is displayed are provided on the user interface screen 800. Since the first display region 801 and the second display region 802 are distinguished from each other, it is possible to display the first mesh data and the second mesh data before recombination by the combining unit 290G in an identifiable manner on the display unit 400. In the first display region 801, the second display region 802, and the third display region 803, coordinate systems of X, Y, and Z are displayed, respectively.

In this embodiment, a combining process of the first three-dimensional data and the second three-dimensional data by the combining unit 290G can be edited. That is, the analysis module 290 includes the editing unit 290H that edits the combining process of the first three-dimensional data and the second three-dimensional data by the combining unit 290G. The editing unit 290H accepts an input for editing the position or shape of at least one three-dimensional data of the first three-dimensional data and the second three-dimensional data. The editing unit 290H can edit the position of the first three-dimensional data in any of the X direction, the Y direction, and the Z direction. The second three-dimensional shape data can be similarly edited.

The editing unit 290H accepts an input of editing of the first three-dimensional data or editing of the second three-dimensional data, and edits the first three-dimensional data or the second three-dimensional data based on the accepted input. Then, the combining unit 290G recombines the first three-dimensional data and the second three-dimensional data based on the input accepted by the editing unit 290H. At this time, the alignment unit 290A can perform the alignment between the first three-dimensional data and the second three-dimensional data based on the first alignment parameter that is the positional relationship between the first three-dimensional data A and the second three-dimensional data B. As a result, it is not necessary to newly accept alignment designation by the user, and convenience can be improved. In addition, when an input of editing the third three-dimensional data and the fourth three-dimensional data is similarly accepted, the editing unit 290H edits the third three-dimensional data and the fourth three-dimensional data based on the accepted input. Then, the combining unit 290G updates and regenerates the combined three-dimensional data based on the input accepted by the editing unit 290H.

For example, when the first three-dimensional data and the second three-dimensional data are combined, the first three-dimensional data and the second three-dimensional data having different initial positions are aligned on the background of the display processing of the user interface screen 810 as illustrated in FIG. 20 as an example, and then combined by the combining unit 290G. A combining result display button 811, an additional shape display button 812, and an original shape display button 813 are provided on the user interface screen 810.

When the user operates the combining result display button 811, the display control unit 255 displays the combined three-dimensional data, which is the combining result, in a display region 814 of the user interface screen 810 at a point in time when the combining of the first three-dimensional data and the second three-dimensional data is completed. The user can confirm the quality of the combining result by viewing the combined three-dimensional data. When there is a defective part, it is also possible to specify an occurring part and an occurring factor thereof. At the time of specification, when the user operates the additional shape display button 812 on the user interface screen 810 as illustrated in FIG. 21, the display control unit 255 displays the second three-dimensional data in the display region 814 of the user interface screen 810, and when the user operates the original shape display button 813 on the user interface screen 810 as illustrated in FIG. 22, the display control unit 255 displays the first three-dimensional data in the display region 814 of the user interface screen 810. As described above, since the first three-dimensional data and the second three-dimensional data can be individually displayed by a switching operation of the user, in a case where a problem is found in the combining result of the combined three-dimensional data, the user can select any one of the first three-dimensional data or the second three-dimensional data, and partially excise or repair the three-dimensional data while confirming the selected three-dimensional data. Note that, the combined three-dimensional data, the first three-dimensional data, and the second three-dimensional data may be displayed on one user interface screen.

An edit button 815 is provided on the user interface screen 810 illustrated in FIG. 21. When the user operates the edit button 815, the display control unit 255 generates and displays a user interface screen 820 for data editing as illustrated in FIG. 23, and accepts an instruction to edit the three-dimensional data by the editing unit 290H. A display region 821 in which an instruction of partial excision, repair, or the like is accepted and three-dimensional data to be edited by the editing unit 290H is displayed based on the instruction, a procedure display region 822 in which an editing procedure is displayed, and a setting region 823 in which a designation method, a selection method, an editing method, or the like of the editing region can be set are provided on the user interface screen 820. When editing such as partial excision or repair of the three-dimensional data is performed on the user interface screen 820, the edited three-dimensional data is stored in the storage device 240.

In a case where the edited three-dimensional data is, for example, the second three-dimensional data, alignment between the edited second three-dimensional data and the first three-dimensional data is executed again by the alignment unit 290A. At this time, the alignment unit 290A can perform the alignment between the edited second three-dimensional data and the first three-dimensional data based on the first alignment parameter. Then, the combining unit 290G generates combined three-dimensional data by combining the edited second three-dimensional data and the first three-dimensional data. The combined three-dimensional data generated in this manner is displayed in the display region 814.

In addition, in a case where the quality of the combined three-dimensional data is poor due to the editing of the second three-dimensional data, the user issues a reacquisition instruction to reacquire the second three-dimensional data acquired by the data acquisition unit 291. When the user operates a recapture button 816 of the user interface screen 810 illustrated in FIG. 20, the acceptance unit 298 accepts the reacquisition instruction to reacquire the second three-dimensional data. In this case, the data acquisition unit 291 acquires fifth mesh data (mesh data for update) and acquires the first mesh data from the storage device 240 based on the reacquisition instruction accepted by the acceptance unit 298, and the alignment unit 290A performs the alignment between the first mesh data and the fifth mesh data. The fifth mesh data is acquired to update the second mesh data. Thus, the alignment unit 290A can perform alignment between the mesh data for update acquired as a substitute for the second mesh data, that is, the fifth mesh data and the first mesh data based on the first alignment parameter. The alignment is started when an alignment button 817 of the user interface screen 810 illustrated in FIG. 20 is operated.

When the acceptance unit 298 accepts the reacquisition instruction, the display control unit 255 can also display the recommended arrangement posture based on the first three-dimensional data on the display unit 400. The recommended arrangement posture is the posture calculated by the posture calculation unit 293 as described above. The recommended arrangement posture is displayed on the display unit 400, and thus, it is possible to grasp the arrangement posture with a large amount of additional data.

Then, the combining unit 290G combines the first mesh data and the fifth mesh data aligned by the alignment unit 290A, and updates the combined three-dimensional data. The updated combined three-dimensional data is displayed in the display region 814. As described above, the first alignment parameter that is the alignment parameter of the first mesh data and the second mesh data may be used for combining the first mesh data and the fifth mesh data aligned by the alignment unit 290A. That is, the first alignment parameter that is the alignment parameter of the first three-dimensional data A and the second three-dimensional data B is associated with the combined three-dimensional data AB, and when the reacquisition instruction to reacquire the second three-dimensional data is accepted, alignment between the first three-dimensional data A and newly acquired three-dimensional data B′ instead of the second three-dimensional data B may be performed by using the first alignment parameter associated with the combined three-dimensional data AB to generate new combined three-dimensional data AB′. In a case where the combined three-dimensional data is updated, the combining unit 290G may discard the combined three-dimensional data before update. In addition, when the first mesh data and the third mesh data aligned by the alignment unit 290A are combined, the combining unit 290G may discard the second mesh data, which is the mesh data before update. That is, since the mesh data that does not constitute the combined three-dimensional data is unnecessary data, it is possible to suppress wasteful occupation of the storage region by discarding the mesh data. When the unnecessary data is discarded, confirmation may be performed by the user.

Further, the alignment unit 290A executes alignment between the combined three-dimensional data AB′ obtained by combining the first mesh data and the fifth mesh data and the third mesh data. At this time, the alignment unit 290A can perform the alignment between the combined mesh data AB′ obtained by combining the first mesh data and the fifth mesh data and the third mesh data based on the second alignment parameter. Then, the combining unit 290G combines the combined mesh data AB′ and the third mesh data aligned by the alignment unit 290A to generate combined mesh data AB′C. The generated combined mesh data AB′C is displayed in the display region 814.

On the other hand, since the first three-dimensional data, the fifth three-dimensional data, and the third three-dimensional data constituting the combined three-dimensional data are automatically stored as the necessary data in the storage device 240, at least one of the first three-dimensional data, the fifth three-dimensional data, and the third three-dimensional data can be read later. It is possible to execute only the combining processing again by automatically storing individual scan results for noise or misalignment overlooked while repeating the combining processing. For example, as illustrated in FIG. 19, in a case where the combined three-dimensional data ABC is generated after the generation of the combined three-dimensional data AB and then the combined three-dimensional data ABCD is generated, and in a case where the third three-dimensional data C is combined with even the fourth three-dimensional data D without noticing noise contamination, the step can be resumed from the middle by recombining the third three-dimensional data C with the combined three-dimensional data AB.

As described above, the combined three-dimensional data may include information indicating a combining order of the three-dimensional data, and the information indicating the combining order of the three-dimensional data can be stored in the storage device 240 in a state of being associated with the combined three-dimensional data. The combining unit 290G combines the first mesh data and the third mesh data aligned by the alignment unit 290A based on the information indicating the combining order corresponding to the second three-dimensional data.

### (Alignment of CAD Data)

In a case where the actual workpiece W is arranged to match the CAD data displayed on the display unit 400, the user needs to move the workpiece W on the rotary stage 143, but the invention is not limited thereto, and the CAD data may be moved to match the actual workpiece W. That is, it may be difficult for the user to arrange the actual workpiece W so as to match the CAD data while viewing the display unit 400 because it is necessary to perform the arrangement while viewing both the display unit 400 and the rotary stage 143. Further, since the camera that captures the actual workpiece W and the line of sight of the user face each other, the user performs an operation while viewing a mirror image, which causes difficulty. Therefore, in order to improve the convenience of the user, it is possible to mount a function (alignment function) capable of aligning the actual workpiece and the CAD data by the user moving the CAD data while viewing the display unit 400 without moving the actual workpiece W on the three-dimensional scanner 1.

Hereinafter, details of the alignment function will be described with reference to the flowchart illustrated in FIG. 24. In the following description, the alignment is referred to as overlay alignment, and the CAD data is referred to as a “virtual object”. In step S100, the controller 200 reads a center position of the rotary stage 143 and the CAD data. In step S101, the controller 200 calculates a virtual ground based on the center position of the rotary stage 143 read in step S100, displays the virtual ground on the display unit 400, and displays the virtual object on the display unit 400 based on the CAD data.

In step S102, the controller 200 determines whether or not a mouse button of the operation unit 250 is pressed near a display position of the virtual object. In a case where the mouse button is not pressed near the display position of the virtual object, the overlay alignment is terminated. On the other hand, in a case where the mouse button is pressed in the vicinity of the display position of the virtual object, the processing proceeds to step S103, and the controller 200 executes virtual object rotation processing by mouse dragging.

The virtual object rotation processing will be described with reference to the flowchart of FIG. 25. In step S200, the controller 200 determines whether or not a rotation button of the operation unit 250 is pressed. In a case where it is determined that the rotation button of the operation unit 250 is pressed, the controller 200 determines in step S201 whether or not a moving direction of a mouse of the operation unit 250 is close to horizontal. In a case where the moving direction of the mouse is not close to horizontal, the processing proceeds to step S202. On the other hand, in a case where the moving direction of the mouse is close to horizontal, the processing proceeds to step S203, and the controller 200 fixes a rotation axis of the virtual object to an axis perpendicular to the virtual ground. In step S204, the controller 200 extracts a horizontal component of the amount of movement of the mouse. In step S205, the controller 200 calculates a posture rotated according to the horizontal component extracted around the fixed axis. In step S206, the controller 200 adjusts a positional relationship between the virtual object and the virtual ground. In step S207, the display of the virtual object is updated. In step S208, the controller 200 determines whether or not the mouse button is released. In a case where the mouse button is not released, the processing returns to step S201.

In step S202, the controller 200 determines whether or not the moving direction of the mouse of the operation unit 250 is close to vertical. In a case where the moving direction of the mouse is close to vertical, the processing proceeds to step S209, and the controller 200 fixes the rotation axis of the virtual object to right and left axes in the line-of-sight direction. In step S210, the controller 200 extracts a vertical component of the amount of movement of the mouse. In step S211, the controller 200 calculates a posture rotated according to the vertical component extracted around the fixed axis, and the processing proceeds to step S206.

In a case where it is determined in step S202 that the moving direction of the mouse is not close to vertical, the processing proceeds to step S212, and the amount of movement of the mouse is extracted. In step S213, a posture rotated in any direction according to the amount of movement of the mouse is calculated, and the processing proceeds to step S206.

In a case where NO is determined in step S200, the processing proceeds to step S214, and the amount of movement of the mouse is extracted. In step S215, a posture rotated in any direction according to the amount of movement of the mouse is calculated, and the processing proceeds to step S206.

Thereafter, the processing proceeds to step S104 illustrated in FIG. 24, and the controller 200 calculates a distance between the virtual object and the virtual ground. In step S105, the controller 200 extracts a surface close to the virtual ground, among surfaces of the virtual object. In step S106, the controller 200 calculates a degree of grounding between the surface of the virtual object and the virtual ground. In step S107, the controller 200 determines whether or not there is an extracted surface for which the degree of grounding is not calculated. In a case where there is the extracted surface for which the degree of grounding is not calculated, a next surface is selected in step S108, and the processing proceeds to step S106.

In a case where there is no extracted surface of which the degree of grounding is not calculated, the processing proceeds to step S109, and the controller 200 selects a surface having a highest degree of grounding. In step S110, the controller 200 calculates a posture in which the selected surface and the virtual ground are grounded. In step S111, the display of the virtual object is updated to the calculated posture.

The flowchart of FIG. 26 illustrates processing of adjusting the positional relationship between the virtual object and the virtual ground. In step S300, the controller 200 calculates the distance between the virtual object and the virtual ground. In step S301, the controller 200 determines whether or not the virtual object is buried in the virtual ground. In a case where YES is determined in step S301, the processing proceeds to step S302, the virtual object is pushed up onto the virtual ground, and the processing proceeds to step S303. In a case where NO is determined in step S301, the processing proceeds to step S303. In step S303, the controller 200 determines whether or not the virtual object is floating from the virtual ground. In a case where YES is determined in step S303, the processing proceeds to step S304, and the virtual object is grounded on the virtual ground.

The flowchart of FIG. 27 illustrates stage surface detection processing. In step S400, the three-dimensional shape of the rotary stage 143 is measured and acquired by the controller 200. In step S401, the controller 200 obtains a position of the stage surface (mounting surface 142) from the three-dimensional shape of the rotary stage 143. In step S402, the controller 200 calculates height information of the stage surface with respect to the camera position based on the obtained plane position. In step S403, the calculated stage surface height information is stored in the storage device 240 or the like.

In step S404, the controller 200 determines whether or not a dedicated chart is held. The dedicated chart is, for example, a calibration board. In a case where NO is determined in step S404, the processing proceeds to step S405, and a center position of the stage is calculated based on an irregularity shape on the stage surface with known design values. In a case where YES is determined in step S404, the processing proceeds to step S406, and the dedicated chart is rotated and measured from a plurality of directions to calculate the stage center position. In step S407, the stage center position is stored in the storage device 240 or the like.

FIG. 28 is a flowchart illustrating an example of processing of the alignment function in a case where rotation and movement of the virtual object are performed. Steps S500, S501, and S502 are the same as steps S100, S101, and S102 in FIG. 24, respectively. In addition, steps S505 to S512 are the same as steps S104 to S111 in FIG. 24, respectively.

In step S503, virtual object rotation and movement by mouse drag are executed. FIG. 28 is a flowchart illustrating an example of processing in a case where the rotation and movement of the virtual object are performed. In step S600, the controller 200 determines whether or not the moving direction of the mouse of the operation unit 250 is close to horizontal. In a case where the moving direction of the mouse is not close to horizontal, the processing proceeds to step S601. On the other hand, in a case where the moving direction of the mouse is close to horizontal, the processing proceeds to step S602, and the controller 200 fixes the rotation axis of the virtual object to an axis perpendicular to the virtual ground. In step S603, the controller 200 extracts a horizontal component of the mouse movement amount. In step S604, the controller 200 calculates a posture rotated according to the horizontal component extracted around the fixed axis. In step S605, the controller 200 adjusts a positional relationship between the virtual object and the virtual ground. In step S606, the display of the virtual object is updated. In step S607, the controller 200 determines whether or not the mouse button is released. In a case where the mouse button is not released, the processing returns to step S603.

In step S601, the controller 200 determines whether or not the moving direction of the mouse of the operation unit 250 is close to vertical. In a case where the moving direction of the mouse is close to vertical, the processing proceeds to step S608, and the controller 200 fixes the rotation axis of the virtual object to right and left axes in the line-of-sight direction. In step S609, the controller 200 extracts a vertical component of the amount of movement of the mouse. In step S610, the controller 200 calculates a posture rotated according to the vertical component extracted around the fixed axis, and the processing proceeds to step S611. In step S611, the controller 200 adjusts a positional relationship between the virtual object and the virtual ground. In step S612, the display of the virtual object is updated. In step S613, the controller 200 determines whether or not the mouse button is released. In a case where the mouse button is not released, the processing returns to step S609.

In a case where the moving direction of the mouse is not close to vertical, the processing proceeds to step S614, and the controller 200 extracts the amount of movement of the mouse. In step S615, the controller 200 calculates a posture rotated in any direction according to the amount of movement of the mouse, and the processing proceeds to step S616. In step S616, the controller 200 adjusts a positional relationship between the virtual object and the virtual ground. In step S617, the display of the virtual object is updated. In step S618, the controller 200 determines whether or not the mouse button is released. In a case where the mouse button is not released, the processing returns to step S614.

In step S513 of FIG. 28, the controller 200 calculates a distance between the virtual object and the virtual tilting table. In step S514, a surface close to a virtual tilting table is extracted, among surfaces of the virtual object. In step S515, a degree of grounding between the surface of the virtual object and the virtual tilting table is calculated. In step S516, it is determined whether there is an extracted surface for which a degree of grounding is not calculated. In a case where there is an uncalculated extracted surface, the processing proceeds to step S517, a next surface is selected, and the processing proceeds to step S515. When there is no uncalculated extracted surface, the processing proceeds to step S518, and a surface having a highest degree of grounding is selected. In step S519, a posture in which the selection surface and the virtual tilting table are grounded is calculated. In step S520, a positional relationship among the virtual object, the virtual ground, and the virtual tilting table is adjusted.

FIG. 30 is a flowchart illustrating another example of processing in a case where rotation and movement of the virtual object are performed. Steps S700 to S705 are the same as steps S200 to S205 in FIG. 25, respectively. In addition, steps S707 to S715 are the same as steps S207 to S215 in FIG. 25, respectively. In step S706, the controller 200 adjusts a positional relationship among the virtual object, the virtual ground, and the virtual tilting table. The virtual tilting table virtually indicates a tilting table provided on the rotary stage 143. The tilting table provided on the rotary stage 143 is configured such that, for example, a tilted angle with respect to a horizontal plane can be changed in a plurality of ways and the workpiece W can be tilted by mounting the workpiece W on the tilting table.

FIG. 31 is a flowchart illustrating an example of processing in a case where the positional relationship among the virtual object, the virtual ground, and the virtual tilting table is adjusted. In step S800, the controller 200 calculates distances between the virtual object, the virtual ground, and the virtual tilting table. In step S801, the controller 200 determines whether or not the virtual object is buried in the virtual ground or the virtual tilting table. In a case where YES is determined in step S801, the processing proceeds to step S802, the virtual object is pushed up onto the virtual ground or the virtual tilting table, and then the processing proceeds to step S803. In a case where NO is determined in step S801, the processing proceeds to step S803. In step S803, the controller 200 determines whether or not the virtual object is floating from the virtual ground or the virtual tilting table. In a case where YES is determined in step S803, the processing proceeds to step S804, and the virtual object is grounded to the virtual ground or the virtual tilting table.

As described above, the same determination as that of the rotary stage 143 is executed in a space where the virtual object is present, and a physical constraint condition that the virtual object is grounded to the rotary stage 143 is introduced. As a result, since the rotation and the translation are limited to the same degree of freedom as the actual workpiece W, the alignment by the user becomes easy.

In addition, although an unstable posture may occur during mouse drag of the operation unit 250, a stable posture is calculated at a timing when the mouse is released, and the posture is automatically corrected to a posture in which the degree of grounding between the rotary stage 143 and the virtual object becomes high. Since an actual possible posture of the workpiece W is also present in a limited degree of freedom, the alignment becomes easy.

In addition, the rotation operation by the mouse drag of the operation unit 250 is limited such that only one axis of the roll, the pitch, and the yaw with respect to the workpiece is simultaneously rotated. As a result, the virtual object on the rotary stage 143 can be rotated while maintaining a grounding state of the rotary stage 143, and the alignment becomes easier.

In addition, when the rotation of the rotary stage 143 and the display of the virtual object are interlocked, it may be difficult to grasp the positional relationship in the depth direction when the image is captured from the fixed camera as one of difficulties of alignment. On the other hand, the rotation of the rotary stage 143 and the display state of the virtual object are interlocked, and thus, it is possible to grasp the positional relationship with the virtual object when an object of the rotary stage 143 is captured from different angles, and to use the captured image for alignment.

Further, in the case of a structure capable of tilting the rotary stage 143 as described above, tilt information and the like can be interlocked with the alignment function. For example, a portion for inputting the tilt information (tilted angle information) of the rotary stage 143 is provided in the application, and the controller 200 acquires the information. Thus, the virtual object can be interlocked with the virtual space, and the virtual object can take the posture in consideration of the tilted angle of the rotary stage 143.

In addition, in the scan in a case where there is no reference model illustrated in FIG. 6, the processing may proceed to step SA5 without calculating the evaluation value and calculating the recommended arrangement posture in SA4. In this case, in step SA5, for example, the posture calculation unit 293 calculates, as the recommended arrangement posture, a posture obtained by rotating the partial scan model of the workpiece W arranged in the first arrangement posture acquired by the data acquisition unit 291 by a constant rotation angle about a predetermined axis such as a rotation axis horizontal to the mounting surface 140. Then, the display control unit 255 can display the recommended arrangement posture calculated by the posture calculation unit 293 on the display unit 400. Here, for example, the posture calculation unit 293 may calculate the recommended arrangement posture by estimating the rotation axis horizontal to the mounting surface 140 and rotating the workpiece W by a certain rotation angle such as 60 degrees or 90 degrees about the rotation axis. In step SA6, the user determines whether or not the posture displayed on the display unit 400 is a desired posture. In a case where the posture is not the desired posture, the processing proceeds to step SA7, and the arrangement posture of the workpiece W is adjusted on the computer graphics. In step SA8, the posture calculation unit 293 can calculate and update the evaluation value for the adjusted posture, but can skip to step SA6.

In a case where it is determined in step SA6 that the posture is the desired posture, the processing proceeds to step SA9, and the analysis module 290 generates the workpiece (model) of computer graphics in the determined arrangement posture. In step SA10, the user mounts the workpiece W on the mounting surface 142 at a temporary position. Then, the workpiece W is captured together with the mounting surface 142 by the light reception unit 120, and the live image is acquired by the data acquisition unit 291 and displayed on the display unit 400. While viewing the live image on the display unit 400, the user moves or rotates the actual workpiece W until the actual workpiece W overlaps the workpiece of the computer graphics.

In step SA11, the user determines whether or not the actual workpiece W is mounted so as to overlap the workpiece of the computer graphics. In a case where the actual workpiece W cannot be mounted so as to overlap the workpiece of the computer graphics, the processing proceeds to step SA5, and the arrangement posture is adjusted. In a case where the actual workpiece W is mounted so as to overlap the workpiece of the computer graphics, since the workpiece W is in the second arrangement posture, the processing proceeds to step SA12, and the measurement unit 100 scans the workpiece W arranged in the second arrangement posture. In step SA12, the light projection unit 110 of the measurement unit 100 irradiates the workpiece W arranged in the second arrangement posture with the measurement light. The light reception unit 120 of the measurement unit 100 receives the measurement light reflected by the workpiece W. The light reception signal output from the light reception unit 120 is received by the point cloud acquisition unit 263a, and the second point cloud data of the workpiece W is generated. The mesh data generation unit 263b acquires the second point cloud data acquired by the point cloud acquisition unit 263a, processes the acquired second point cloud data, and converts the data into second mesh data. In step SA12, the second mesh data obtained by the processing in step SA12 is acquired as the second three-dimensional data (step SA13). The second three-dimensional data is stored in the storage device 240.

In step SA14, the alignment unit 290A included in the analysis module 290 aligns the first three-dimensional data (three-dimensional data of the workpiece arranged in the first arrangement posture) acquired by the data acquisition unit 291 and the second three-dimensional data based on the relative positional relationship calculated by the arithmetic unit 294. At the time of this alignment, the overlap region extracted by the extraction unit 290B included in the analysis module 290 is used.

In addition, as for an example of the scan processing in a case where there is the reference model such as the CAD data of the workpiece W or the measured three-dimensional data illustrated in FIG. 17, the processing may proceed to step SG4 without the posture calculation unit 293 calculating the evaluation value and calculating the recommended arrangement posture in step SG3. In this case, in step SG4, the display control unit 255 displays the CAD data or the measured three-dimensional data on the display unit 400. The posture of the CAD data or the measured three-dimensional data at this time may be, for example, a posture of the CAD data or the measured three-dimensional data with respect to the scanner determined by matching the coordinate system of the CAD data or the measured three-dimensional data with the scanner coordinate system. In step SG4, the user can adjust the posture of the CAD data or the measured three-dimensional data based on this posture. In step SG5, the user determines whether or not the candidate posture displayed on the display unit 400 is a desired posture. In a case where the posture is not the desired posture, the processing proceeds to step SG6, and the arrangement posture of the workpiece W is adjusted on the computer graphics. In step SG7, the posture calculation unit 293 calculates and updates the evaluation value with respect to the adjusted posture, but the processing may be skipped and the processing may proceed to step SG5.

In a case where it is determined in step SG5 that the posture is the desired posture, the processing proceeds to step SG8, and the analysis module 290 generates the workpiece (model) of computer graphics in the determined arrangement posture. The display control unit 255 superimposes the workpiece of the computer graphics generated by the analysis module 290 on the live image acquired by the data acquisition unit 291 and displays the superimposed image on the display unit 400. In step SG9, the user mounts the workpiece W on the mounting surface 142 at a temporary position. Then, the workpiece W is captured together with the mounting surface 142 by the light reception unit 120, and the live image is acquired by the data acquisition unit 291 and displayed on the display unit 400. While viewing the live image on the display unit 400, the user moves or rotates the actual workpiece W until the actual workpiece W overlaps the workpiece of the computer graphics.

In step SG10, the user determines whether or not the actual workpiece W is mounted so as to overlap the workpiece of the computer graphics. In a case where the actual workpiece W cannot be mounted so as to overlap the workpiece of the computer graphics, the processing proceeds to step SG4, and the arrangement posture is adjusted. In a case where the actual workpiece W is mounted so as to overlap the workpiece of the computer graphics, since the workpiece W is in the first arrangement posture, the processing proceeds to step SG11, and the measurement unit 100 scans the workpiece W arranged in the first arrangement posture. In step SG12, the first three-dimensional data is acquired. In step SG13, the alignment unit 290A performs the alignment between the measured first three-dimensional data and the CAD data that is the reference model. In step SG14, the analysis module 290 acquires the aligned CAD model or the measured three-dimensional data.

In step SG15, the posture candidate is proposed, and the processing proceeds to step SG16. For example, as for the posture candidate, the posture of the CAD data or the measured three-dimensional data may be changed according to a predetermined rule with respect to the desired posture determined in step SG5. As an example of the predetermined rule, there is a case where the CAD data or the measured three-dimensional data is rotated by 60 degrees with respect to the desired posture determined in step SG5 with one axis of the scanner coordinate system as the rotation axis. In addition, the user may select a rotation angle range within 90 degrees, for example. In step SG16, the user selects the posture candidate, and then the processing proceeds to step SG17. In a case where the posture is not the desired posture, after adjustment in step SG18, the evaluation value is updated in step SG19, and then the processing proceeds to step SG17. Step SG19 may be skipped.

In a case where the posture is the desired posture, the processing proceeds to step SG20, and the display control unit 255 superimposes the workpiece of the computer graphics generated by the analysis module 290 on the live image acquired by the data acquisition unit 291 and displays the superimposed image on the display unit 400. Here, the workpiece of the computer graphics may be the first three-dimensional data or the reference model acquired in step SG12. In addition, the first three-dimensional data and the reference model may be simultaneously displayed on the display unit 400, or may be switched and displayed.

In step SG21, the user moves or rotates the actual workpiece W until the actual workpiece W overlaps the workpiece of the computer graphics while viewing the live image on the display unit 400.

In step SG22, the user determines whether or not the actual workpiece W is mounted so as to overlap the workpiece of the computer graphics. In a case where the actual workpiece W cannot be mounted so as to overlap the workpiece of the computer graphics, the processing proceeds to step SG16, and another arrangement posture is selected. In a case where the actual workpiece W is mounted so as to overlap the workpiece of the computer graphics, the processing proceeds to step SG23, and the measurement unit 100 scans the workpiece W in the arrangement posture (second arrangement posture). In step SG24, the alignment unit 290A performs alignment with the acquired second three-dimensional data, and in step SG25, the partial scan model is acquired. In step SG26, the alignment unit 290A executes alignment processing of the three-dimensional model, and the combining unit 290G executes the combining processing. In step SG27, the user determines whether or not there is the part requiring scanning. When there is the part requiring scanning, the processing proceeds to step SG12. When there is no scan part, the full-surface scan model is acquired in step SG28. The full-surface scan model acquired in step SG28 may be output together with the CAD model or the measured three-dimensional data in which the alignment processing is executed by the alignment unit 290A in step SG26. Further, the full-surface scan model and the CAD model or the measured three-dimensional data may be displayed in a state of being aligned on the display unit 400.

In the present embodiment, the CAD data or the measured three-dimensional data is used as the reference model in order to acquire the combined three-dimensional data of the workpiece W. However, after the combined three-dimensional data of the workpiece W is acquired in a state where there is no reference model, it is also possible to perform alignment with the CAD data or the measured three-dimensional data. The reading unit 292 reads the three-dimensional data of the workpiece W and the CAD data from the storage unit 240. Subsequently, the resolution conversion unit 290E read by the reading unit 292 converts at least the three-dimensional data of the workpiece W into three-dimensional data having the first resolution lower than the resolution acquired by the data acquisition unit 291. Subsequently, the shape feature extraction unit 290C extracts the partial region (key point) to be used for calculation of the shape feature from the three-dimensional data of the first resolution and the CAD data. Subsequently, the analysis module 290 samples the periphery of the partial region, and the shape feature extraction unit 290C calculates the shape feature vector from the vicinity of the point sampled by the analysis module 290. Subsequently, the analysis module 290 compares the shape feature vector of the three-dimensional data obtained by the shape feature extraction unit 290C with the shape feature vector of the CAD data, and the alignment unit 290A aligns the three-dimensional data with the CAD data based on the comparison of the shape feature vectors. The shape feature vector of the pair candidate can be extracted by comparing the shape feature vectors, and the positional relationship (rotation and translation) between the point clouds can be obtained by the RANSAC or the deep learning based method by using the points of the pair candidate.

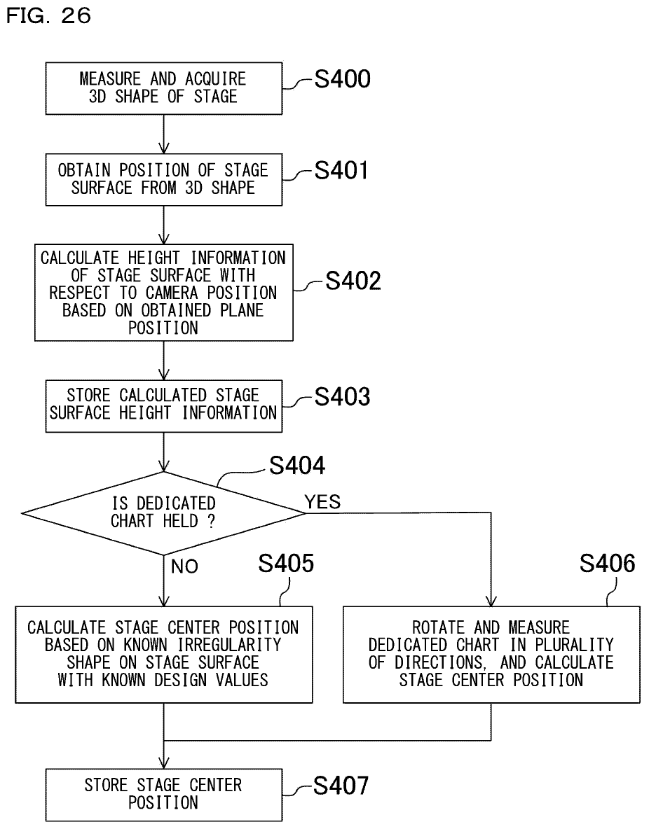

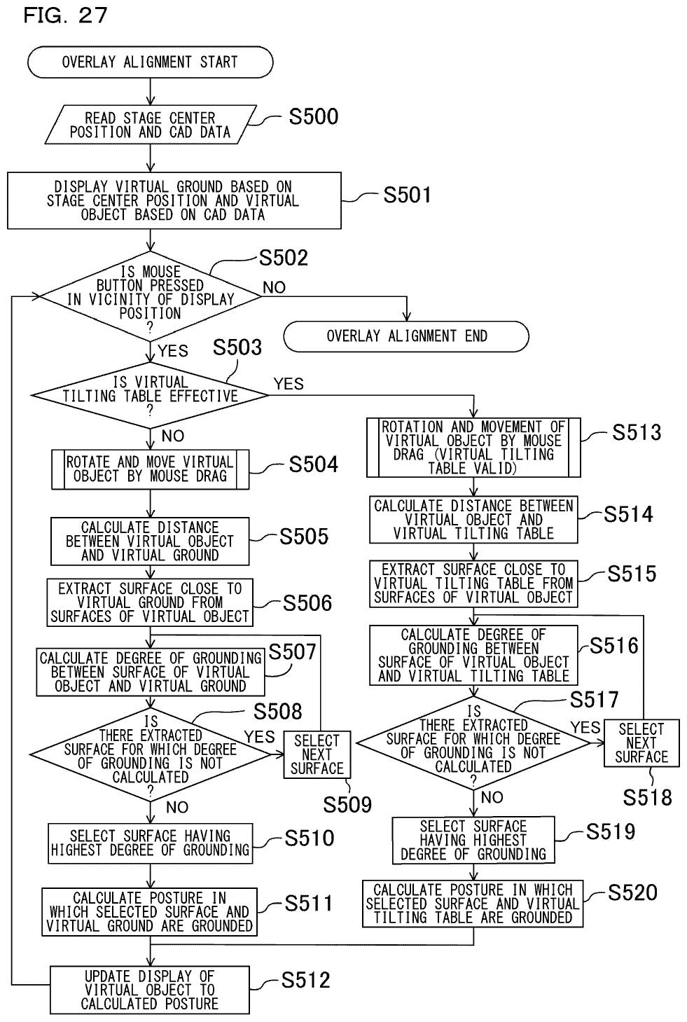

In addition, after alignment between the combined three-dimensional data and the CAD data is completed, the analysis module 290 can automatically execute the comparison between the CAD data and the three-dimensional data. FIG. 32 illustrates an example of analysis in which a color map is displayed by comparing the scan data of the workpiece W and the three-dimensional shape of the CAD data, calculating a difference in dimension between the scan data and the CAD data, and assigning a color corresponding to a degree of difference. The analysis module 290 calculates, for each mesh, a difference in shape between the three-dimensional data of the workpiece W obtained by the data acquisition unit 291 and the CAD data based on the result of alignment by the alignment unit 290A and the CAD data read by the reading unit 292, and assigns color information corresponding to the degree of difference for each mesh. Then, the display control unit 255 displays a color map in which a color is assigned for each mesh based on the color information for at least one of the three-dimensional data and the CAD data on the display unit 400. In addition, after alignment by the alignment unit 290A, the analysis module 290 may compare the three-dimensional data with the CAD data, and the display control unit 255 may display the color map on the display unit 400, based on the acceptance unit 298 accepting an instruction to assign the analysis setting or start the comparative analysis. In this case, the user can assign detailed settings for the comparison.

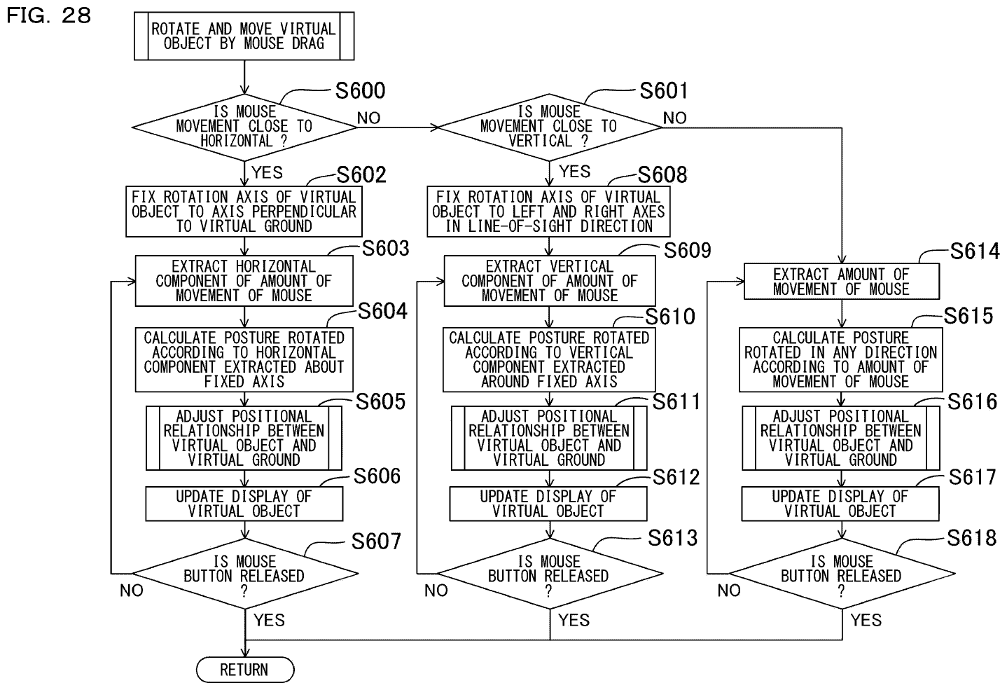

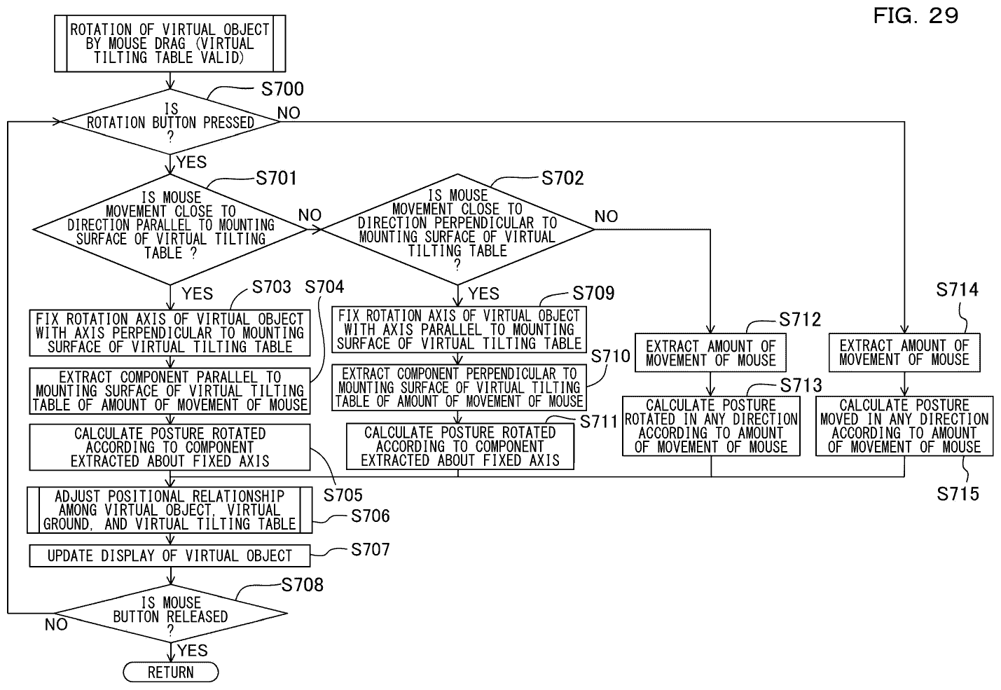

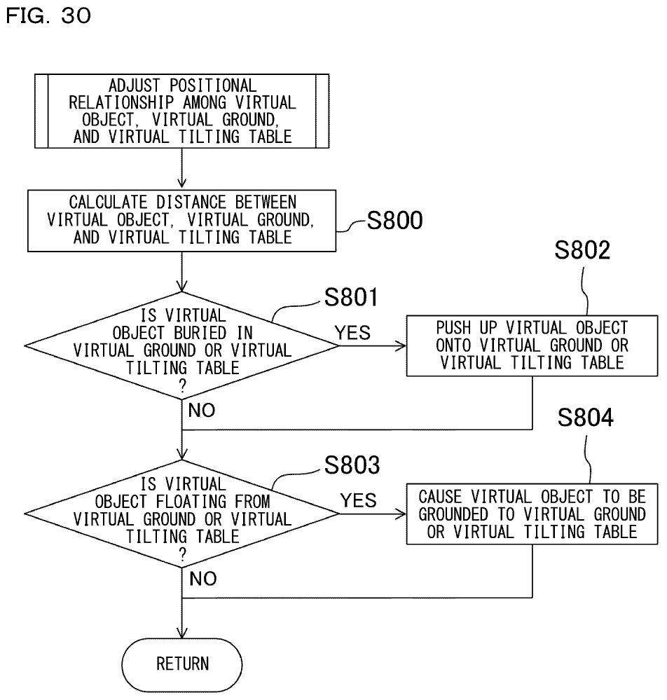

In addition, FIG. 33A illustrates an example in which cross-section measurement is performed on the three-dimensional data of the workpiece W. The user designates a surface on which the cross-section measurement is performed on the three-dimensional data of the workpiece W, and instructs a type and an assignment position of an analysis tool to be executed for a cross-section. The analysis tool is, for example, measurement contents such as a distance between two points and an angle formed by a surface and a surface. The analysis module 290 accepts the instruction and executes analysis on the instructed surface of the three-dimensional data of the workpiece W based on the instruction.

FIG. 33B illustrates an example in which cross-section measurement is performed on the CAD data. The user designates a surface on which the cross-section measurement is performed on the CAD data, and instructs a type and an assignment position of an analysis tool to be executed for the cross-section. The analysis module 290 accepts the instruction and executes analysis on the instructed surface of the CAD data based on the instruction. The analysis module 290 can compare a result obtained by executing the cross-section measurement on the three-dimensional data with a result obtained by executing the cross-section measurement on the CAD data, and the display control unit 255 displays a comparison result on the display unit 400.

In addition, cross-section measurement can be performed on data in which the three-dimensional data of the workpiece W and the CAD data are aligned. The data in which the three-dimensional data of the workpiece W and the CAD data are aligned is obtained by the alignment between the three-dimensional data of the workpiece W and the CAD data by the alignment unit 290A. The user designates a surface on which the cross-section measurement is performed on the data in which the workpiece W and the CAD data are aligned, and instructs the type and the assignment position of the analysis tool to be executed for the cross section. The analysis tool is, for example, measurement contents such as a distance between two points and an angle formed by a surface and a surface. The analysis module 290 accepts the instruction and executes analysis on the instructed surface of the data in which the three-dimensional data of the workpiece W and the CAD data are aligned based on the instruction. The analysis module 290 can execute the cross-section measurement on the data in which the three-dimensional data and the CAD data are aligned. For example, the comparison may be performed based on a difference in dimension between the CAD data and the scan data. The display control unit 255 may display the comparison result on the display unit 400.

The above-described embodiment is merely an example in all respects, and should not be construed in a limiting manner. Further, all modifications and changes falling within the equivalent scope of the claims are within the scope of the invention.

As described above, the invention can be used to generate pieces of three-dimensional data of various workpieces.

What is claimed is:

1. A three-dimensional scanner that generates combined three-dimensional data of a workpiece by generating pieces of three-dimensional data of the workpiece arranged in different arrangement postures and combining the pieces of three-dimensional data, the three-dimensional scanner comprising:
a data acquisition unit that acquires first three-dimensional data of the workpiece arranged in a first arrangement posture;
a posture calculation unit that calculates an arrangement posture different from the first arrangement posture based on the first three-dimensional data acquired by the data acquisition unit;
an overlap region estimation unit that estimates an overlap region between the three-dimensional data to be acquired by the data acquisition unit in a state of being arranged in the arrangement posture calculated by the posture calculation unit and the first three-dimensional data acquired by the data acquisition unit; and
a display control unit that displays an evaluation index based on the amount of overlap region estimated by the overlap region estimation unit on a display unit.

2. The three-dimensional scanner according to claim 1, wherein
the posture calculation unit calculates a plurality of arrangement postures different from the first arrangement posture based on the first three-dimensional data acquired by the data acquisition unit, and
the three-dimensional scanner further includes
an additional data amount estimation unit that estimates the amount of additional data to be added to the first three-dimensional data by acquiring the three-dimensional data by the data acquisition unit in a state of being arranged in one arrangement posture for each of the plurality of arrangement postures calculated by the posture calculation unit.

3. The three-dimensional scanner according to claim 2, wherein the evaluation index is an index based on the amount of additional data estimated by the additional data amount estimation unit and the amount of overlap region estimated by the overlap region estimation unit.

4. The three-dimensional scanner according to claim 2, further comprising:
a specifying unit that specifies one candidate posture from among the plurality of arrangement postures calculated by the posture calculation unit based on the evaluation index,
wherein the display control unit displays the one candidate posture specified by the specifying unit on the display unit.

5. The three-dimensional scanner according to claim 2, wherein the additional data amount estimation unit moves the first three-dimensional data so as to have each arrangement posture, and estimates the amount of additional data based on an orientation of a normal vector after the movement.

6. The three-dimensional scanner according to claim 5, wherein the additional data amount estimation unit estimates the amount of three-dimensional data facing an imaging unit of the three-dimensional scanner based on an inner product value of the orientation of the normal vector after the movement from a predetermined viewpoint and a line-of-sight direction of the imaging unit, and estimates that the amount of additional data is larger as the amount of three-dimensional data facing the imaging unit is larger.

7. The three-dimensional scanner according to claim 1, wherein the display control unit displays the evaluation index in a numerical form or a graph form on the display unit.

8. The three-dimensional scanner according to claim 3, wherein the display control unit displays each of an evaluation index based on the amount of additional data estimated by the additional data amount estimation unit and an evaluation index based on the amount of overlap region estimated by the overlap region estimation unit on the display unit.

9. The three-dimensional scanner according to claim 2, wherein the display control unit displays an evaluation index in each of the plurality of arrangement postures calculated by the posture calculation unit on the display unit.

10. The three-dimensional scanner according to claim 1, wherein the overlap region estimation unit estimates a degree of feature based on a distribution of points in the overlap region.

11. The three-dimensional scanner according to claim 10, further comprising:
a specifying unit that specifies one candidate posture from among the plurality of arrangement postures calculated by the posture calculation unit based on the evaluation index; and
an additional data amount estimation unit that estimates the amount of additional data to be added to the first three-dimensional data by acquiring the three-dimensional data by the data acquisition unit in a state of being arranged in one arrangement posture for each of the plurality of arrangement postures calculated by the posture calculation unit,
wherein the specifying unit specifies the one candidate posture based on the amount of additional data estimated by the additional data amount estimation unit, the amount of overlap region estimated by the overlap region estimation unit, and the degree of feature estimated by the overlap region estimation unit.

12. The three-dimensional scanner according to claim 1, wherein the posture calculation unit calculates a candidate posture based on a size of a contact area with a mounting surface in each of the plurality of arrangement postures.

13. The three-dimensional scanner according to claim 4, further comprising an acceptance unit that accepts an operation input for adjusting the one candidate posture specified by the specifying unit.

14. The three-dimensional scanner according to claim 2, wherein
the data acquisition unit acquires combined three-dimensional data in which the first three-dimensional data of the workpiece arranged in the first arrangement posture and second three-dimensional data of the workpiece arranged in a second arrangement posture different from the first arrangement posture are combined,
the posture calculation unit calculates an arrangement posture different from the first arrangement posture based on the combined three-dimensional data, and
the additional data amount estimation unit estimates the amount of additional data to be added to the combined three-dimensional data by acquiring the three-dimensional data by the data acquisition unit in the arrangement posture calculated by the posture calculation unit.

15. The three-dimensional scanner according to claim 1, further comprising:
a stage control unit that controls a rotation operation of a stage on which the workpiece is mounted,
wherein the posture calculation unit calculates a plurality of arrangement postures by virtually rotating the first three-dimensional data about a rotation axis of the stage.

16. The three-dimensional scanner according to claim 2, further comprising:
an evaluation unit that calculates an evaluation index in each of the plurality of arrangement postures based on the amount of additional data in each of the plurality of arrangement postures calculated by the posture calculation unit and the amount of overlap region, and calculates a comprehensive evaluation index based on each evaluation index.

17. A three-dimensional measurement method for generating combined three-dimensional data of a workpiece by generating pieces of three-dimensional data of the workpiece arranged in different arrangement postures and combining the pieces of three-dimensional data, the three-dimensional measurement method comprising:
acquiring first three-dimensional data of the workpiece arranged in a first arrangement posture;
calculating an arrangement posture different from the first arrangement posture based on the acquired first three-dimensional data;
estimating an overlap region between the three-dimensional data to be acquired by a data acquisition unit in a state of being arranged in the calculated arrangement posture and the first three-dimensional data acquired by the data acquisition unit; and
displaying an evaluation index based on the estimated amount of overlap region on a display unit.

18. A storage medium storing a three-dimensional measurement program for causing a computer to execute a three-dimensional measurement method for generating combined three-dimensional data of a workpiece by generating pieces of three-dimensional data of the workpiece arranged in different arrangement postures and combining the pieces of three-dimensional data,
wherein the three-dimensional measurement method includes
acquiring first three-dimensional data of the workpiece arranged in a first arrangement posture,
calculating an arrangement posture different from the first arrangement posture based on the acquired first three-dimensional data,
estimating an overlap region between the three-dimensional data to be acquired by a data acquisition unit in a state of being arranged in the calculated arrangement posture and the first three-dimensional data acquired by the data acquisition unit, and
displaying an evaluation index based on the estimated amount of overlap region on a display unit.
